(19) United States
(12) Patent Application Publication
(10) Pub. No.: US 2023/0336274 A1
(43) Pub. Date: Oct. 19, 2023

(54) CODEWORD BIT INTERLEAVING SCHEME FOR MULTILAYER TRANSMISSIONS IN WIRELESS COMMUNICATION SYSTEM

(71) Applicant: HUAWEI TECHNOLOGIES CO., LTD., Shenzhen (CN)

(72) Inventors: Alberto Giuseppe PEROTTI, Segrate (IT); Branislav M. POPOVIC, Kista (SE)

(73) Assignee: HUAWEI TECHNOLOGIES CO., LTD., Shenzhen (CN)

(21) Appl. No.: 18/304,599

(22) Filed: Apr. 21, 2023

Related U.S. Application Data
(63) Continuation of application No. PCT/EP2020/079895, filed on Oct. 23, 2020.

(51) Int. Cl. H04L 1/00; H04W 28/04

(52) U.S. Cl. CPC H04L 1/0071; H04L 1/0057; H04L 1/0064; H04W 28/04; H04B 7/0413

(57) ABSTRACT

A codeword bit interleaving scheme for multilayer transmissions in a wireless communication system. The codeword bit interleaving scheme involves dividing columns of an interleaving matrix into at least two disjoint column groups based on transmission qualities (e.g., SNRs) of data transmission layers (e.g., MIMO layers). The column groups are then filled with codeword bits, starting with writing information bits into the column group(s) corresponding to the high-quality data transmission layers. After that, the column groups are all merged to restore the initial column arrangement of the interleaving matrix, and the codeword bits are read from the interleaving matrix row-wise and mapped to modulation symbols. The modulation symbols are in turn mapped to the data transmission layers themselves.

### CROSS-REFERENCE TO RELATED APPLICATIONS

This application is a continuation of International Application No. PCT/EP2020/079895, filed on Oct. 23, 2020, the disclosure of which is hereby incorporated by reference in its entirety.

### TECHNICAL FIELD

The embodiments generally relate to the field of wireless communications and a codeword bit interleaving scheme for multilayer transmissions in a wireless communication system.

### BACKGROUND

The fifth generation (5G) of mobile wireless communication networks, such as the 3rd Generation Partnership Project (3GPP) New Radio (NR), use a Multiple-Input Multiple-Output (MIMO) approach in order to achieve very high data rates for transmission between a base station (BS) or gNodeB (gNB) and a user equipment (UE). The MIMO approach exploits multipath propagation over a radio channel by using multiple transmitter and receiver antennas in order to create multiple spatial layers (also referred to as MIMO layers) whereon information can be transmitted concurrently. The propagation phenomena that occur on the radio channel often cause large imbalances among Signal-to-Noise Ratios (SNRs) of the MIMO layers. Large SNR imbalances may cause performance degradations if they are not properly addressed.

In the NR, any data stream exchanged between the gNB and the UE includes a sequence of data blocks. Each data block is independently encoded into a codeword by using an error correction code. The NR relies on Low-Density Parity-Check (LDPC) codes for error correction. Codeword bits are then interleaved and modulated to be transmitted to the gNB or the UE over the MIMO layers.

However, the NR uses the same modulation and code rate on all MIMO layers even though the MIMO layers may have large SNR imbalances. To guarantee given transmission reliability, modulation/code rate selection is done based on a transmission quality peculiar to the worst (i.e., low-SNR) MIMO layers. This makes it impossible to fully exploit the transmission quality of the high-SNR MIMO layers, thereby resulting in limited bit rates.

### SUMMARY

This summary is provided to introduce a selection of concepts in a simplified form that are further described below in the detailed description. This summary is not intended to identify key features of the embodiments, nor is it intended to be used to limit the scope of the embodiments.

It is an objective of the embodiments to provide solutions that enable codeword bit interleaving for multilayer transmissions in a wireless communication system.

According to a first aspect, an apparatus for a wireless communication system is provided. The apparatus includes a processor, a memory coupled to the processor, and a transceiver. The memory stores processor-executable instructions. When executed, the processor-executable instructions cause the processor to operate as follows. At first, the processor receives a codeword to be sent over data transmission layers. Each of the data transmission layers has a transmission quality, and the codeword is obtained using a linear code. The codeword has a codeword length E and includes codeword bits. The codeword bits include at least one information bit and at least one parity bit. Then, the processor proceeds with interleaving the codeword bits by using a matrix with n rows and k columns, where n and k are selected based on a predefined modulation scheme and the codeword length E. Each column may correspond to one of the data transmission layers. The interleaving operation includes:
arranging, into at least one first column group, the columns corresponding to the data transmission layers whose transmission qualities are equal to or above a threshold;
arranging, into at least one second column group, the columns corresponding to the data transmission layers whose transmission qualities are below the threshold;
writing the codeword bits row-wise into the at least one first column group and the at least one second column group, starting with writing the at least one information bit row-wise into the at least one first column group;
merging the at least one first column group and the at least one second column group to restore the matrix; and
reading the codeword bits column-wise from the matrix.

When the interleaving operation is finished, the processor uses the predefined modulation scheme to obtain a modulation symbol for the codeword bits read from each column of the matrix. After that, the processor maps the modulation symbols to the data transmission layers. Next, the transceiver sends the mapped modulation symbols to a target apparatus in the wireless communication system.

By performing the interleaving operation in this way, the apparatus according to the first aspect may map the information bits of the codeword to the data transmission layers with high transmission qualities (e.g., high SNRs) even when the codeword is transmitted on multiple data transmission layers with significantly different transmission qualities. In turn, such mapping may improve decoding performance in the target apparatus, thereby achieving smaller error rates and larger spectral efficiency.

In one embodiment of the first aspect, the predefined modulation scheme has a modulation order Qₘ, and n is equal to the modulation order Qₘ. At the same time, k is obtained by applying a floor or ceiling function to a ratio of the codeword length E to the modulation order Qₘ. By so doing, it is possible to create a more efficient interleaving matrix, thereby increasing the efficiency of the whole interleaving operation.

In one embodiment of the first aspect, the processor is further configured, before the interleaving operation, to determine the modulation order Qₘ of the predefined modulation scheme based on the transmission qualities of the data transmission layers. By so doing, it is possible to select the modulation order Qₘ more suitable for the given data transmission layers, thereby increasing the efficiency of the whole interleaving operation.

In one embodiment of the first aspect, the predefined modulation scheme defines a mapping of a Qₘ-tuple of the codeword bits for each column of the matrix to the modulation symbol, and the processor is further configured to:
determine bit capacities of the codeword bits in each Qₘ-tuple based on the transmission qualities of the data transmission layers; and
based on the determined bit capacities, determine: (i) a number G of the at least one first column group (802) and the at least one second column group (804) into which the columns of the matrix (800) are to be arranged, and (ii) a correspondence of each of the data transmission layers to the at least one first column group (802) or the at least one second column group (804).

By so doing, it is possible to increase the efficiency of grouping the columns of the matrix used in the interleaving operation, thereby increasing the efficiency of the whole interleaving operation.

In one embodiment of the first aspect, the processor is further configured, prior to the transceiver sending the mapped modulation symbols to the target apparatus, to generate a control message and cause the transceiver to send the control message to the target apparatus. The control message may include at least one of the following: the modulation order Qₘ; the codeword length E; the number G of the at least one first column group and the at least one second column group used when interleaving the codeword bits; and the correspondence of each of the data transmission layers to the at least one first column group or the at least one second column group. By so doing, it is possible to provide the target apparatus with information about the codeword bit interleaving scheme used by the apparatus according to the first aspect, thereby allowing the target apparatus to perform deinterleaving and, consequently, decoding operations more efficiently and faster.

In one embodiment of the first aspect, the codeword is obtained using the linear code selected from one of a turbo code, a systematic code, a systematic polar code, and a LDPC code. This may make the apparatus according to the first aspect more flexible in use because, for example, LDPC codes may be used in the 5G NR.

In one embodiment of the first aspect, the predefined modulation scheme includes one of a quadrature amplitude modulation (QAM) scheme, a Phase Shift Keying (PSK) modulation scheme, and a Quadrature PSK (QPSK) modulation scheme. This may make the apparatus according to the first aspect more flexible in use because it may choose among the modulation schemes depending on particular application.

In one embodiment of the first aspect, the processor is further configured to determine the transmission qualities of the data transmission layers in advance based on uplink reference signals in case of Time-Division Duplexing (TDD) communications or downlink reference signals in case of Frequency-Division Duplexing (FDD) communications. This may make the apparatus according to the first aspect more flexible in use because it may be adapted for different duplex communication links.

In one embodiment of the first aspect, the data transmission layers include MIMO spatial layers. This may allow the apparatus according to the first aspect to be used in MIMO wireless communication systems, thereby increasing its flexibility in use.

According to a second aspect, a method for wireless communications is provided. The method starts with the step of receiving a codeword to be sent over data transmission layers.

Each of the data transmission layers has a transmission quality, and the codeword is obtained using a linear code. The codeword has a codeword length E and includes codeword bits. The codeword bits include at least one information bit and at least one parity bit. Then, the method proceeds to the step of interleaving the codeword bits by using a matrix with n rows and k columns, where n and k are selected based on a predefined modulation scheme and the codeword length E. Each of the columns corresponds to one of the data transmission layers. The interleaving step v the following sub-steps:
arranging, into at least one first column group, the columns corresponding to the data transmission layers whose transmission qualities are equal to or above a threshold;
arranging, into at least one second column group, the columns corresponding to the data transmission layers whose transmission qualities are below the threshold;
writing the codeword bits row-wise into the at least one first column group and the at least one second column group, starting with writing the at least one information bit row-wise into the at least one first column group;
merging the at least one first column group and the at least one second column group to restore the matrix; and
reading the codeword bits column-wise from the matrix.

When the interleaving step is finished, the method proceeds to the step of obtaining, by using the predefined modulation scheme, a modulation symbol for the codeword bits read from each column of the matrix. After that, the next step of the method is initiated, in which the modulation symbols are mapped to the data transmission layers. Next, the method goes on to the step of sending the mapped modulation symbols to a target wireless communication apparatus.

By performing the interleaving step in this way, it is possible to map the information bits of the codeword to the data transmission layers with high transmission qualities (e.g., high SNRs) even when the codeword is transmitted on multiple data transmission layers with significantly different transmission qualities. In turn, such mapping may improve decoding performance in the target wireless communication apparatus, thereby achieving smaller error rates and larger spectral efficiency.

In one embodiment of the second aspect, the predefined modulation scheme has a modulation order Qₘ, and n is equal to the modulation order Qₘ. At the same time, k is obtained by applying a floor or ceiling function to a ratio of the codeword length to the modulation order Qₘ. By so doing, it is possible to create a more efficient interleaving matrix, thereby increasing the efficiency of the whole interleaving step.

In one embodiment of the second aspect, the method further includes, before the interleaving step, the step of determining the modulation order Qₘ of the predefined modulation scheme based on the transmission qualities of the data transmission layers. By so doing, it is possible to select the modulation order Qₘ more suitable for the given data transmission layers, thereby increasing the efficiency of the whole interleaving step.

In one embodiment of the second aspect, the predefined modulation scheme defines a mapping of a Qₘ-tuple of the codeword bits for each column of the matrix to the modulation symbol. In this embodiment, the method further includes the steps of:
determining bit capacities of the codeword bits in each Qₘ-tuple based on the transmission qualities of the data transmission layers; and
based on the determined bit capacities, determining: (i) a number G of the at least one first column group (802) and the at least one second column group (804) into which the columns of the matrix (800) are to be arranged, and (ii) a correspondence of each of the data transmission layers to the at least one first column group (802) or the at least one second column group (804).

By so doing, it is possible to increase the efficiency of grouping the columns of the matrix used in the interleaving step, thereby increasing the efficiency of the whole interleaving step.

In one embodiment of the second aspect, the method further includes, before the sending step, the step of generating and sending a control message to the target wireless communication apparatus. The control message may include at least one of the following: the modulation order Qₘ; the codeword length E; the number G of the at least one first column group and the at least one second column group used when interleaving the codeword bits; and the correspondence of each of the data transmission layers to the at least one first column group or the at least one second column group. By so doing, it is possible to provide the target wireless communication apparatus with information about the codeword bit interleaving scheme used in the method according to the second aspect on the transmitting side, thereby allowing the target wireless communication apparatus to deinterleave and, consequently, decode the codeword bits more efficiently and faster.

In one embodiment of the second aspect, the codeword is obtained using the linear code selected from one of a turbo code, a systematic code, a systematic polar code, and a LDPC code. This may make the method according to the second aspect more flexible in use because, for example, LDPC codes may be used in the 5G NR.

In one embodiment of the second aspect, the predefined modulation scheme includes one of a QAM scheme, a PSK modulation scheme, and a QPSK modulation scheme. This may make the method according to the second aspect more flexible in use because it provides the possibility of choosing among the modulation schemes depending on particular application.

In one embodiment of the second aspect, the method further includes the step of determining the transmission qualities of the data transmission layers in advance based on uplink reference signals in case of Time-Division Duplexing (TDD) communications or downlink reference signals in case of Frequency-Division Duplexing (FDD) communications. This may make the method according to the second aspect more flexible in use because it may be adapted for different duplex communication links.

In one embodiment of the second aspect, the data transmission layers include MIMO spatial layers. This may allow the method according to the second aspect to be used in MIMO wireless communication systems, thereby increasing its flexibility in use.

According to a third aspect, a computer program product is provided. The computer program product includes a non-transitory computer-readable storage medium storing a computer code. When executed by at least one processor, the computer code causes the at least one processor to perform the method according to the second aspect. By using such a computer program product, it is possible to simplify the implementation of the method according to the second aspect in any computing device, such, for example, as the apparatus according to the first aspect.

Other features and advantages of the embodiments will be apparent upon reading the following detailed description and reviewing the accompanying drawings.

### BRIEF DESCRIPTION OF THE DRAWINGS

The embodiments are explained below with reference to the accompanying drawings, in which:

FIG. 1 shows a block diagram of a conventional transmitter used to perform NR LDPC-coded transmission;

FIG. 2 shows an exemplary structure of a first codeword segment for initial transmission performed by the conventional transmitter shown in FIG. 1;

FIG. 3 explains interleaving, modulation and layer-mapping operations performed in the conventional transmitter shown in FIG. 1;

FIG. 4 shows dependences of bit capacities βₗ^{(Q}^{ₘ}⁾ on SNR=1/σ_{G}² (assuming unit average modulation symbol energy) for different modulation schemes used in the conventional transmitter shown in FIG. 1;

FIG. 5 shows a block diagram of a wireless communication apparatus in accordance with one exemplary embodiment;

FIG. 6 shows a block diagram of a processor used in the apparatus shown in FIG. 5 in accordance with one exemplary embodiment;

FIG. 7 shows a flowchart of a wireless communication method in accordance with one exemplary embodiment;

FIG. 8 explains the interleaving step, modulation step and mapping step of the method shown in FIG. 7 in case of using two column groups;

FIG. 9 shows dependencies βₗ⁽⁴⁾(SNR), l=1, . . . ,4, for a numerical example with 16QAM (Qₘ=4);

FIG. 10 shows matrices used by a conventional interleaver of the conventional transmitter shown in FIG. 1 and an interleaver of the processor shown in FIG. 6, respectively, and corresponding bit capacities for a first transmission in the numerical example;

FIG. 11 shows matrices used by the conventional interleaver of the conventional transmitter shown in FIG. 1 and the interleaver of the processor shown in FIG. 6, respectively, and corresponding bit capacities for a second transmission in the numerical example;

FIG. 12 shows dependencies of a Block Error Rate (BLER) on SNR for the two transmissions in the numerical example;

FIGS. 13A and 13B show the BLER performance of QPSK-modulated and 16QAM-modulated LDPC-coded transmission on v=2 MIMO layers and G=2 column groups;

FIGS. 14A and 14B show a dependence of a metric Δ_{CC} on SNR for the same code rates and modulations as used for FIGS. 13A and 13B; and

FIGS. 15A and 15B show the BLER performance of the QPSK-modulated and 16QAM-modulated LDPC-coded transmission for various layer SNR differences.

### DETAILED DESCRIPTION OF THE EMBODIMENTS

Various embodiments are further described in more detail with reference to the accompanying drawings. However, the embodiments may be embodied in many other forms and should not be construed as limited to any certain structure or function discussed in the following description. In contrast, these embodiments are provided to make the description of detailed and complete.

According to the detailed description, it will be apparent to the ones skilled in the art that the scope of the description encompasses any embodiment thereof irrespective of whether this embodiment is implemented independently or in concert with any other embodiment. For example, the apparatus and method herein may be implemented in practice by using any numbers of the embodiments provided herein.

The word “exemplary” is used herein in the meaning of “used as an illustration”. Unless otherwise stated, any embodiment described herein as “exemplary” should not be construed as preferable or having an advantage over other embodiments.

According to the exemplary embodiments herein, a user equipment or UE for short may refer to a mobile device, a mobile station, a terminal, a subscriber unit, a mobile phone, a cellular phone, a smart phone, a cordless phone, a personal digital assistant (PDA), a wireless communication device, a desktop computer, a laptop computer, a tablet computer, a gaming device, a netbook, a smartbook, an ultrabook, a medical device or medical equipment, a biometric sensor, a wearable device (for example, a smart watch, smart glasses, a smart wrist band, etc.), an entertainment device (for example, an audio player, a video player, etc.), a vehicular component or sensor, a smart meter/sensor, an unmanned vehicle (e.g., an industrial robot, a quadcopter, etc.), industrial manufacturing equipment, a global positioning system (GPS) device, an Internet-of-Things (IoT) device, an Industrial IoT (IIoT) device, a machine-type communication (MTC) device, a group of Massive IoT (MIoT) or Massive MTC (mMTC) devices/sensors, or any other suitable device configured to support wireless communications. In some embodiments, the UE may refer to at least two collocated and inter-connected UEs thus defined.

As used in the exemplary embodiments herein, a Radio Access Network node or RAN node for short may relate to a fixed point of communication for the UE in a particular wireless communication network. The RAN node may be referred to as a base transceiver station (BTS) in terms of the 2G communication technology, a NodeB in terms of the 3G communication technology, an evolved NodeB (eNodeB) in terms of the 4G communication technology, and a gNB in terms of the 5G New Radio (NR) communication technology. The RAN node may serve different cells, such as a macrocell, a microcell, a picocell, a femtocell, and/or other types of cells. The macrocell may cover a relatively large geographic area (for example, at least several kilometers in radius). The microcell may cover a geographic area less than two kilometers in radius, for example. The picocell may cover a relatively small geographic area, such, for example, as offices, shopping malls, train stations, stock exchanges, etc. The femtocell may cover an even smaller geographic area (for example, a home). Correspondingly, the RAN node serving the macrocell may be referred to as a macro node, the RAN node serving the microcell may be referred to as a micro node, and so on.

According to the exemplary embodiments herein, a wireless communication network, in which the UE and the RAN node communicate with each other, may refer to a cellular or mobile telecommunications network, a Wireless Local Area Network (WLAN), a Wireless Personal Area Networks (WPAN), a Wireless Wide Area Network (WWAN), a satellite communication (SATCOM) system, or any other type of wireless communication networks. Each of these types of wireless communication networks supports wireless communications according to one or more communication protocol standards. For example, the cellular network may operate according to the Global System for Mobile Communications (GSM) standard, the Code-Division Multiple Access (CDMA) standard, the Wide-Band Code-Division Multiple Access (WCDM) standard, the Time-Division Multiple Access (TDMA) standard, or any other communication protocol standard, the WLAN may operate according to one or more versions of the IEEE 802.11 standards, the WPAN may operate according to the Infrared Data Association (IrDA), Wireless USB, Bluetooth, or ZigBee standard, and the WWAN may operate according to the Worldwide Interoperability for Microwave Access (WiMAX) standard.

As used in the exemplary embodiments herein, a wireless communication system may refer to a set of at least two entities (e.g., one UE and one RAN node, two UEs, two RAN nodes, or the like) that are configured to intercommunicate via any wireless communication network (like the one described above). Said intercommunication may be performed via a radio channel established between, for example, a UE and a gNB. To achieve very high data rates for data transmissions, a MIMO approach may be applied to the radio channel The MIMO approach involves employing multiple transmit antennas and multiple receive antennas (i.e., a MIMO channel) for data transmission. The MIMO channel formed by the multiple transmit and receive antennas may be decomposed into independent channels. Each of the independent channels may be also referred to as a spatial subchannel or a spatial or MIMO layer of the MIMO channel. The MIMO approach makes it possible to perform spatial multiplexing or spatial diversity. The spatial multiplexing refers to the transmission of multiple data streams simultaneously via multiple spatial layers of the MIMO channel

The propagation phenomena that occur on the radio channel often cause large imbalances among the Signal-to-Noise Ratios (SNRs) of the MIMO layers. Large SNR imbalances may cause performance degradations. Table 1 given below shows an example of MIMO layer SNRs for a different number of NR Physical Downlink Shared Channel (PDSCH) transmissions. Each PDSCH transmission is assumed to have a different number of MIMO layers available therefor. The number of MIMO layers depends on the radio channel. In Table 1, cells which are not filled with any numbers imply that the associated MIMO layers are not available in the corresponding PDSCH transmission. In the NR, only one channel quality (e.g., SNR) is reported for multiple MIMO layers and only one modulation and code rate are used for transmission on the MIMO layers. Thus, the transmission performance of the whole MIMO channel is limited by the lowest quality among the MIMO layers (e.g., for the initial transmission in the example given in Table 1, it is 8.6 dB which represents the SNR of layer 4).

TABLE 1
Example of MIMO layers SNRs in an NR MIMO transmission.

| Transmission | Layer 1 SNR | Layer 2 SNR | Layer 3 SNR | Layer 4 SNR |
|---|---|---|---|---|
| # | [dB] | [dB] | [dB] | [dB] |
| 1 | 27.7 | 19.7 | 11.9 | 8.6 |
| 2 | 27.8 | 20.2 | 15.3 | 10.6 |
| 3 | 29.4 | 24.1 | 12.6 | — |
| 4 | 30.2 | 17.8 | — | — |
| 5 | 32.7 | 25.8 | 20.5 | 14.1 |

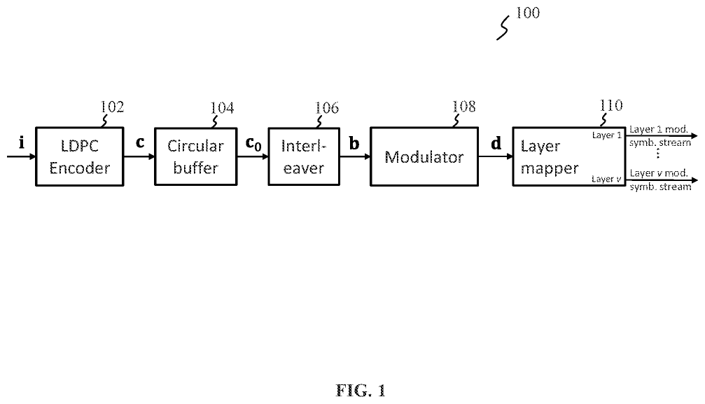

FIG. 1 shows a block diagram of a conventional transmitter 100 used to perform NR LDPC-coded transmission. The transmitter 100 may be part of a wireless communication apparatus, such, for example, as a UE or a gNB. As shown in FIG. 1, the transmitter 100 includes an LDPC encoder 102, a circular buffer 104, an interleaver 106, a modulator 108, and a layer mapper 110, which are used in the transmitter 100 in the order they are mentioned. It should be noted that, in the NR, any data stream exchanged, for example, between the gNB and the UE includes a sequence of data blocks. The data blocks are processed by the transmitter 100 independently from each other. Each data block may be independently encoded by the LDPC encoder 102 using an error correction code (i.e., an LDPC code in this case), interleaved by the interleaver 106, modulated by the modulator 108 and mapped by the layer mapper 110 to v MIMO layers, as shown in FIG. 1.

Let us now consider the operation of the transmitter 100 in more detail.

The LDPC encoder 102 maps a data block i=(i₁, . . . , i_{K}) to a codeword c=(c₁, . . . , C_{N}). The codeword c is written to the circular buffer 104 in the transmitter 100. In an initial transmission, a first codeword segment c₀=(cₑ,e=1, . . . ,E), E>K, is read from the circular buffer 104 and sent to the interleaver 106 where it is subjected to bit interleaving or, in other words, bit rearrangement or swapping. Thus, the initial transmission has an error correction code rate equal to R_{C}=K/E.

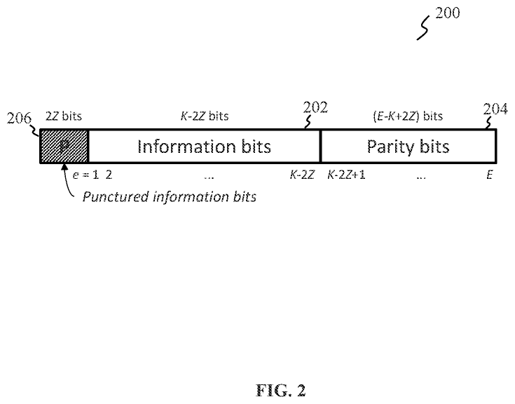

FIG. 2 shows an exemplary structure 200 of the first codeword segment c₀ for the initial transmission performed by the transmitter 100. As shown in FIG. 2, the first codeword segment co includes two main parts: a first part 202 containing information bits (conventionally called systematic bits) and a second part 204 containing parity bits (also called parity-check bits). The first codeword segment co may be optionally obtained by removing or puncturing a part of the information bits in order to accelerate LDPC decoder convergence. Such a part of removed or punctured bits is denoted as “206” in FIG. 2. In general, the first codeword segment c₀ can be written as:

C₀=(c₁, c₂, . . . , c_{E})=(j₁, j₂, . . . , j_{K-2Z}, p₁, . . . , p_{E-K+2Z}),

Where j₁=i_{2Z+1}, j₂i_{2Z+2}, . . . , j_{K-2Z}=i_{K} are the information bits, and p₁, . . . , p_{E-K+2Z} are the parity bits. The initial 2Z information bits (here, Z denotes a lifting factor used to lift a parity check matrix of a given LDPC code) are punctured, i.e., represent the punctured bits which are neither written to the circular buffer 104 nor transmitted by the transmitter 100.

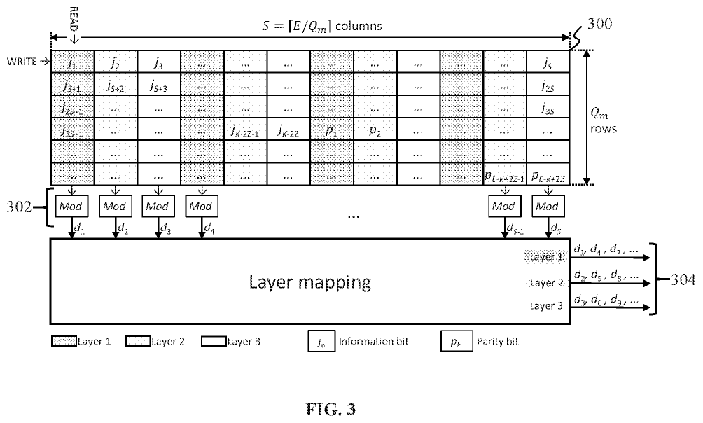

FIG. 3 explains the interleaving, modulation and layer-mapping operations performed in the transmitter 100. As follows from FIG. 3, the interleaver 106 uses a rectangular array or matrix 300 (which is also referred to as an interleaving matrix) with a number of rows equal to a modulation order Qₘ of a pre-selected modulation scheme and a number of columns S=E/Qₘ. The bits of c₀ are written into the matrix 300 row-wise, left to right, starting from the top row. As the initial part of c₀ includes the (K−2Z) information bits, the └(K−2Z)/S┘ top rows are filled with the information bits. The remaining information bits, if any, are written into the

$$( ⌊ \frac{K - 2 Z}{S} ⌋ + 1 ) - th row .$$

The rest of the matrix 300 is filled with the parity bits.

Once the bits of co are all written into the matrix 300, they are read from the matrix 300 column-wise, top to bottom, starting from the left-most column, thereby producing an output b=(b₁, . . . , b_{E}) of the interleaver 106. The n-th output bit of the interleaver 106 is therefore bₙ=c_{((n-1)mod Q}_{ₘ}_{)S+└n/Q}_{ₘ}_{┘+1}, where mod denotes the modulo operation. The s -th column (where s=1, . . . , S) of the interleaver 106 produces a Qₘ-tuple of bits (b_{Q}_{ₘ}₍ₛ₋₁₎₊₁₎, b_{Q}_{ₘ}₍ₛ₋₂₎₊₂₎, . . . , b_{Q}_{ₘ}ₛ) which is then mapped to a complex modulation symbol dₛ. It therefore turns out that the initial bits of any Qₘ-tuple are the information bits. Given that the bits in a Qₘ-tuple are provided with non-increasing levels of reliability, this yields that the information bits are mapped to high-capacity bit channels. Each bit channel may be considered as a physical resource used to convey a codeword bit to a receiver by mapping the codeword bit to a modulation symbol. The modulator 108 thus produces a modulation symbol vector d=(d₁, . . . d_{S}), which is denoted as 302 in FIG. 3.

The layer mapper 110 maps the modulation symbols 302 from d to v MIMO layers 304, where 1≤v≤4. The layer mapper 110 may form v modulation symbol vectors—one for each MIMO layer, where the l-th vector can be written as dₗ=(dₗ, dₗ₊ᵥ, dₗ₊₂ᵥ, . . . ), l=1, . . . , v. It should be noted that the columns of the matrix 300 which are related to the same MIMO layer are shown in FIG. 3 by using the same dotted-pattern fill (e.g., the columns provided with the densest dotted-pattern fill correspond to MIMO layer 1). In further steps (not shown in FIG. 3), the layer-mapped symbols are pre-coded and mapped to time-frequency resource elements, then modulated, for example, by using Orthogonal Frequency Division Multiplexing (OFDM), and transmitted to the receiver, for example, of another UE or gNB.

The above-described transmission procedure for the first codeword segment co is further repeated in respect of the rest (overlapping and/or non-overlapping) codeword segments of the codeword c one by one. Each subsequent codeword segment may be read from the circular buffer 104, interleaved by using the matrix 300, and mapped to the corresponding modulation symbol vector 302 which, in turn, is mapped to the MIMO layers 304 in order to be transmitted to the receiver.

According to the above-described transmission procedure, the first codeword segment c₀ is transmitted on a number of independent bit channels (where each bit channel is a physical resource corresponding to a bit in a Qₘ-tuple of bits read from the matrix 300) whose capacity—called herein a bit capacity—is jointly determined by the bit position in the Qₘ-tuple (b₁, b₂, . . . , b_{Q}_{ₘ}) that is used to select the modulation symbol d_{S} and by the SNR of the corresponding MIMO layer. The bit capacity βₗ^{(Q}^{ₘ}⁾(SNR) of the l^{th} bit in the Qₘ-tuple (b₁, b₂, . . . b_{Q}_{ₘ}) is defined as the mutual information between that a given bit bₗ and a corresponding log-likelihood ratio (LLR) λₗ. It may be mathematically written as:

βₗ^{(Q}^{ₘ}^{)(SNR)=I(b}ₗ, λₗ),

where I(X, Y) denotes the mutual information between the random variables X and Y, l is the position of the bit in the Qₘ-tuple (l=1, . . . ,Qₘ), and the log-likelihood ratio (LLR) λₗ is defined as follows:

$${λ}_{l} = log \frac{P ( {b}_{l} = 0 \vert y )}{P ( {b}_{l} = 1 \vert y )} ,$$

where y=x+w is the modulation symbol received by the receiver, w is the additive white Gaussian noise (AWGN) with a variance σ_{G}², P(bₗ=0|y) is the likelihood that the bit bₗ is 0 in y, and P(bₗ=1|y) is the likelihood that the bit bₗ is 1 in y.

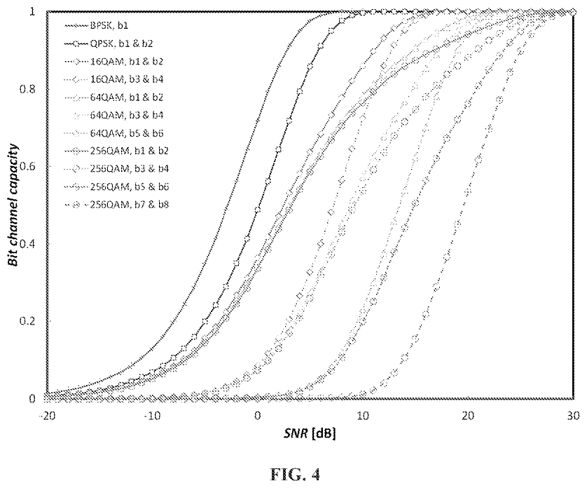

FIG. 4 shows dependences of bit capacities βₗ^{(Q}^{ₘ}^{) on SNR=}1/σ_{G}² (assuming unit average modulation symbol energy) for different modulation schemes used in the transmitter 100. Here, l∈{1, . . . , Qₘ} is the bit position in the Qₘ-tuple. For example, FIG. 4 shows the dependences βₗ^{(Q}^{ₘ}⁾(SNR) for the following modulation schemes: BPSK (Qₘ=1), QPSK (Qₘ=2) and 2^{Q}^{ₘ}-QAM for Qₘ∈{4,6,8} (which corresponds to 16QAM, 64QAM and 256 QAM, respectively). As follows from FIG. 4, the bit channels b_{Q}_{ₘ}ₛ corresponding to the initial positions in the Qₘ-tuple of any 2^{Q}^{ₘ}-QAM modulation scheme correspond to the bit channels with the highest bit capacity. More precisely, for any SNR, any QAM modulation order Qₘ and bit positions l_{q},l₂∈{1, . . . , Qₘ}, l₂>l₁, one can obtain βₗ_{₁}^{(Q}^{ₘ}^{)(SNR)≥β}ₗ_{₂}^{(Q}^{ₘ}⁾(SNR). It is also possible to write

β₁^{(Q}^{ₘ}⁾(SNR)=β₂^{(Q}^{ₘ}⁾(SNR)>β₃^{(Q}^{ₘ}⁾(SNR)=β₄^{(Q}^{ₘ}⁾(SNR)> . . . . . . >β_{Q}_{ₘ}₋₁^{(Q}^{ₘ}⁾(SNR)=β_{Q}_{ₘ}^{(Q}^{ₘ}⁾(SNR).

Thus, the interleaver 106 maps the information bits to the high-capacity bit channels in each Qₘ-tuple. However, the interleaver 106 neglects that the Qₘ-tuples are then mapped to the MIMO layers 304 with different SNRs. As the SNR imbalance between the MIMO layers 304 may be large, mapping the information bits to the initial bits of the Qₘ-tuple regardless of the layer SNR is not sufficient to guarantee a higher bit capacity to the information bits. In fact, when the SNR imbalance between the MIMO layers 304 is large, the last bits of one Qₘ-tuple transmitted on the high-SNR MIMO layer have a higher capacity than the initial bits of another Qₘ-tuple transmitted on the low-SNR MIMO layer.

To eliminate the above-mentioned drawback, the transmission of a single codeword on multiple MIMO layers could be replaced by the transmission of multiple shorter codewords, one for each MIMO layer or group of MIMO layers with similar SNRs. By so doing, each shorter codeword would be encoded and modulated using the best code rate and modulation order to match the layer SNR. However, this solution has the following major drawbacks:
1. the transmission of shorter codewords results in smaller coding gains compared to the transmission of long codewords;
2. scheduling multiple shorter codewords instead of a single codeword requires sending more scheduling messages on a control channel, thereby generating a larger amount of control information and causing potential control channel congestion.

The exemplary embodiments herein provide a solution that allows mitigating or even eliminating the above-sounded drawbacks peculiar to the prior art. For example, the solutions herein relates to a codeword bit interleaving scheme that involves dividing columns of an interleaving matrix (hereinafter referred to as a matrix for short) into at least two disjoint column groups based on transmission qualities (e.g., SNRs) of data transmission layers (e.g., MIMO layers). Two columns are in the same column group if the codeword bits are transmitted on the same layer or different layers with similar transmission qualities. The column groups are then filled with codeword bits, starting with writing information bits into the column group(s) corresponding to the high-quality data transmission layers. Once the information bits are all written, parity bits are then written into the rest column group(s). After that, the column groups are all merged to restore the initial column arrangement of the matrix, and the codeword bits are read from the matrix row-wise and mapped to modulation symbols. The modulation symbols are in turn mapped to the data transmission layers themselves. By so doing, it is possible to allocate information bits of a codeword to high-quality data transmission layers, thereby providing better decoding performance compared to the interleaver 106.

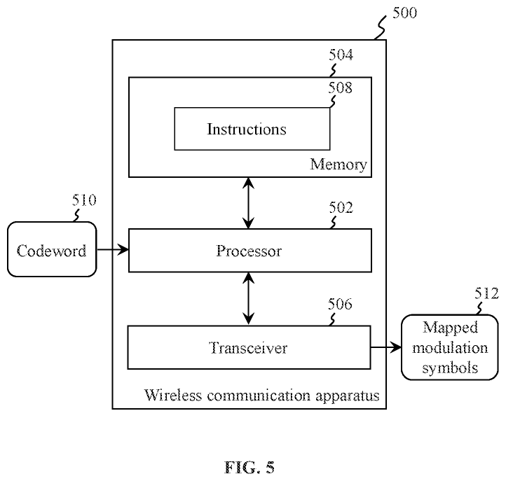

FIG. 5 shows a block diagram of a wireless communication apparatus 500 in accordance with one exemplary embodiment. The apparatus 500 may be implemented as a UE or RAN node or be part of the UE or RAN node. The apparatus 500 includes a processor 502, a memory 504, and a transceiver 506. The memory 504 stores processor-executable instructions 508 which, when executed by the processor 502, cause the processor 502 to receive a codeword 510 and obtain layer-mapped modulation symbols 512, as will be described below in more detail. It should be noted that the number, arrangement, and interconnection of the constructive elements constituting the apparatus 500, which are shown in FIG. 5, are not intended to be any limitation of the embodiments, but merely used to provide a general idea of how the constructive elements may be implemented within the apparatus 500. For example, the processor 502 may be replaced with several processors, as well as the memory 504 may be implemented as an individual storage device coupled to the apparatus 500. Furthermore, the transceiver 506 may be implemented as two devices, with one for a receiving operation and another for a transmitting operation. Irrespective of its implementation, the transceiver 506 is intended to be capable of performing different operations required to transmit the layer-mapped modulation symbols 512, such, for example, as OFDM-modulation, etc.

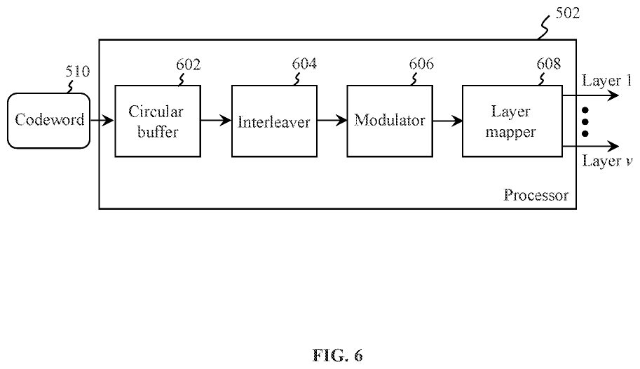

FIG. 6 shows a block diagram of the processor 502 in accordance with one exemplary embodiment. The processor 502 includes the following components: a circular buffer 602, an interleaver 604, a modulator 606, and a layer mapper 608. The circular buffer 602, the interleaver 604, the modulator 606, and the layer mapper 608 are used for the same purposes as the circular buffer 104, the interleaver 106, the modulator 108, and the layer mapper 110, respectively, which are included in the transmitter 100 described above. The processor 502 may optionally include an encoder configured to obtain the codeword 510. The components of the processor 502 may be implemented as hardware and/or software. The hardware implementation of the components may be provided by using a CPU, general-purpose processor, single-purpose processor, microcontroller, microprocessor, application specific integrated circuit (ASIC), field programmable gate array (FPGA), digital signal processor (DSP), complex programmable logic device, or any combination thereof. As an example, the components of the processor 502 may be implemented as two or more microprocessors. The software implementation involves fulfilling the function of each component of the processor 502 by executing a corresponding code, program, routine, command, or the like, which is stored, for example, in the memory 504 together with the processor-executable instructions 506.

Referring back to FIG. 5, the memory 504 may be implemented as a classical nonvolatile or volatile memory used in the modern electronic computing machines. As an example, the nonvolatile memory may include Read-Only Memory (ROM), ferroelectric Random-Access Memory (RAM), Programmable ROM (PROM), Electrically Erasable PROM (EEPROM), solid state drive (SSD), flash memory, magnetic disk storage (such as hard drives and magnetic tapes), optical disc storage (such as CD, DVD and Blu-ray discs), etc. As for the volatile memory, examples thereof include Dynamic RAM, Synchronous DRAM (SDRAM), Double Data Rate SDRAM (DDR SDRAM), Static RAM, etc.

As for the processor-executable instructions 506 stored in the memory 504, they may be configured as a computer-executable code which causes the processor 502 to perform the aspects of the embodiments. The computer-executable code for carrying out operations or steps for the aspects of the embodiments may be written in any combination of one or more programming languages, such as Java, C++, or the like. In some examples, the computer-executable code may be in the form of a high-level language or in a pre-compiled form and may be generated by an interpreter (also pre-stored in the memory 504) on the fly.

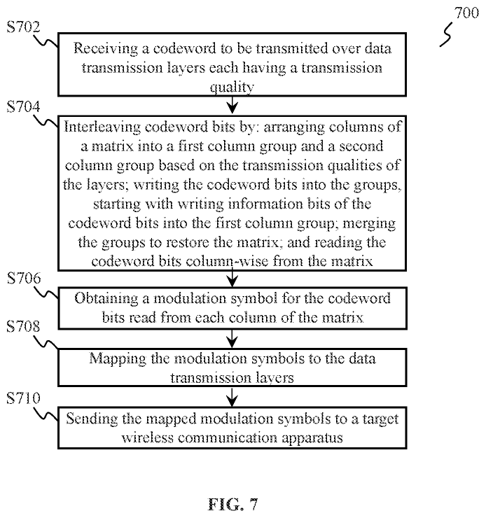

FIG. 7 shows a flowchart of a wireless communication method 700 in accordance with one exemplary embodiment. The method 700 as such describes the operation of the apparatus 500. As shown in FIG. 7, the method 700 starts with a step 5702, in which the processor 502 receives the codeword 510 to be sent over data transmission layers. Each of the data transmission layers has a transmission quality. The data transmission layers may be represented by MIMO layers; however, the embodiments are not limited to this example, and those skilled in the art will easily recognize that the data transmission layers may refer to any spatial layers whereon information may be transmitted concurrently. As for the transmission quality, it may refer to any measure used in the art to compare a level of a desired signal to a level of background noise. One non-restrictive example of the transmission quality is a SNR. Relative to the codeword 510, it may be either obtained by the processor 502 itself or received by the processor 502 from outside (e.g., from a remote server configured to send the codeword 510 to the transceiver 506 which in turn provides it to the processor 502). The codeword is obtained using a linear code. Non-restrictive examples of the linear code include a turbo code, a systematic code, a systematic polar code, a LDPC code, etc. The codeword 510 has a codeword length E and includes codeword bits. The codeword bits include at least one information bit and at least one parity bit. The step 5702 may also involve storing the codeword 510 in the circular buffer 602 if its segmental transmission is scheduled.

Once the codeword 510 is received, the method 700 proceeds to a step 5704, in which the processor 502, i.e., the interleaver 604, interleaves (or, in other words, rearrange/swap) the codeword bits of the codeword 510 by using a matrix with n rows and k columns, where n and k are selected based on a predefined modulation scheme and the codeword length E. The matrix may be created in the same manner as the matrix 300 used by the interleaver 106 of the transmitter 100. In general, n may be equal to the modulation order Qₘ of the predefined modulation scheme, while k is obtained by applying a floor or ceiling function to a ratio of the codeword length E to the modulation order Qₘ. Non-restrictive examples of the predefined modulation scheme include a QAM scheme, a PSK modulation scheme, and a QPSK modulation scheme, etc. Each of the columns of the matrix used in the step S704 of the method 700 corresponds to one of the data transmission layers, which makes it possible to group the columns based on the transmission qualities of the data transmission layers, as described below.

The interleaving step S704 itself is performed as follows. At first, the interleaver 604 arranges, into at least one first column group, the columns corresponding to the data transmission layers whose transmission qualities are equal to or above a threshold, and arranges, into at least one second column group, the columns corresponding to the data transmission layers whose transmission qualities are below the threshold. The threshold depends on particular application and may be any transmission quality value between the minimum transmission quality and the maximum transmission quality of the data transmission layers (e.g., any SNR between the minimum and maximum SNRs of the available MIMO layers to be used for transmission). Then, the interleaver 604 writes the codeword bits row-wise into the first column group(s) and the second column group(s), starting with writing the information bits row-wise into the first column group(s). After that, the interleaver 604 merges the first column group(s) and the second column group(s) to restore the matrix. Said restoration implies a return to the initial column arrangement in the matrix but now with the columns filled with the codeword bits. The interleaving step S704 is finished when the interleaver 604 reads the codeword bits column-wise from the matrix.

When the interleaving step S704 is finished, the method 700 proceeds to a step S706, in which the processor 502, i.e., the modulator 606, obtains, by using the predefined modulation scheme, a modulation symbol for the codeword bits read from each column of the matrix. After that, a next step S708 of the method 700 is initiated, in which the processor 502, i.e., the layer mapper 608, maps the modulation symbols obtained in the step S706 to the data transmission layers. Next, the method 700 goes on to a step S710, in which the transceiver 506 sends the mapped modulation symbols to a target wireless communication apparatus (e.g., another UE or gNB).

In one exemplary embodiment, the method 700 may include a further step, in which the processor 502 (e.g., a special additional hardware or software component included therein) determines the transmission qualities of the data transmission layers in advance, i.e., before the step S702 or the step S704, based on uplink reference signals in case of TDD communications or downlink reference signals in case of FDD communications. For example, if the apparatus 500 is a gNB which uses the MIMO approach when performing the TDD communications, downlink/uplink channel reciprocity is assumed, for which reason the gNB determines downlink SNRs by computing a singular value decomposition of a MIMO channel matrix obtained based on uplink reference signals. If the apparatus 500 is a UE which performs the FDD communications, the UE performs channel estimation, i.e., determines SNRs, based on downlink reference signals.

In one exemplary embodiment, the method 700 may include a further step, in which the processor 502 (e.g., a special additional hardware or software component included therein) determines, before the interleaving step S704, the modulation order Qₘ of the predefined modulation scheme based on the transmission qualities of the data transmission layers. By so doing, it is possible to select the modulation order Qₘ more suitable for the given data transmission layers, thereby increasing the efficiency of the interleaving step S704.

In one exemplary embodiment, the predefined modulation scheme may define a mapping of a Qₘ-tuple of the codeword bits to be read, in the interleaving step S704, from each column of the matrix to the modulation symbol. In this embodiment, the method 700 may include further steps, in which the processor 502 (e.g., a special additional hardware or software component included therein) determines bit capacities of the codeword bits in each Qₘ-tuple based on the transmission qualities of the data transmission layers, and uses the determined bit capacities to determine: (i) a number G of the first column group(s) and the second column group(s) into which the columns of the matrix are to be arranged, and (ii) a correspondence of each of the data transmission layers to the first column group(s) or the second column group(s). By so doing, it is possible to increase the efficiency of grouping the columns of the matrix used in the interleaving step S704, thereby increasing the efficiency of the interleaving step S704 itself.

In one exemplary embodiment, the method 700 may include, before the sending step S710, a further step, in which the processor 502 (e.g., a special additional hardware or software component included therein) generates and sends a control message to the target wireless communication apparatus. The control message may include at least one of the following: the modulation order Qₘ; the codeword length E; the number G of the at least one first column group and the at least one second column group used when interleaving the codeword bits; and the correspondence of each of the data transmission layers to the at least one first column group or the at least one second column group. By so doing, it is possible to provide the target wireless communication apparatus with information about the codeword bit interleaving scheme used by the apparatus 100 when performing the method 700, thereby allowing the target wireless communication apparatus to deinterleave and, consequently, decode the codeword bits more efficiently and faster.

Such a control message may be sent to the target communication apparatus by using the following three control signaling methods:

According to the first control signaling method, a column grouping configuration g=(γ₁, . . . γᵥ) which indicates the column groups is signaled in a control field included in the control message. Each element y, is an integer between 1 and the number G of column groups, which indicates the column group for the corresponding column. For example, the interleaver 604 configured with G=1, g=(1, . . . ,1) coincides with the interleaver 106. The first control signaling method may produce a non-negligible control information overhead, as g can take v^{v} different values, and a bit field of size at least └v log₂ v┘ bits is needed.

According to the second control signaling method, it is assumed that the wireless communication apparatus 100 and the target wireless communication apparatus are configured to sort the data transmission layers in the same order based on the layer SNRs which they have independently determined. Once the layers are sorted according to their SNRs, for each pair of adjacent layers a control bit indicated in the control message signals whether the two layers are in the same column group. As there are v−1 pairs of adjacent layers, a control field of size v−1 bits may be sufficient. At the same time, the second control signaling method suffers from the following drawback: the wireless communication apparatus 100 and the target wireless communication apparatus might produce different layer SNR estimations which could result in different layer orders. However, the swapping of the layers occurs when the SNR difference between the two swapped layers is small, i.e., when the two layers correspond to the same column group. Two layers with large SNR difference are never swapped, because this would imply a large SNR estimation error. The swapping of the layers that will be assigned to the same column group is irrelevant for interleaving/deinterleaving, for which reason the second control signaling method works even with SNR estimation errors.

According to the third control signaling method, it is assumed that the wireless communication apparatus 100 and the target wireless communication apparatus are configured to sort the data transmission layers in the same order based on the layer SNRs which they have independently determined, so as to determine the same sequence of layers sorted according to their own SNRs. A control field signals the number G of groups between 1 and v; the G−1 largest SNR gaps between consecutive layers in the sorted sequence of layers are used as group-separation SNR boundaries. As there can be at most v column groups, a control field of size log₂ v bits may be sufficient to have in the control message.

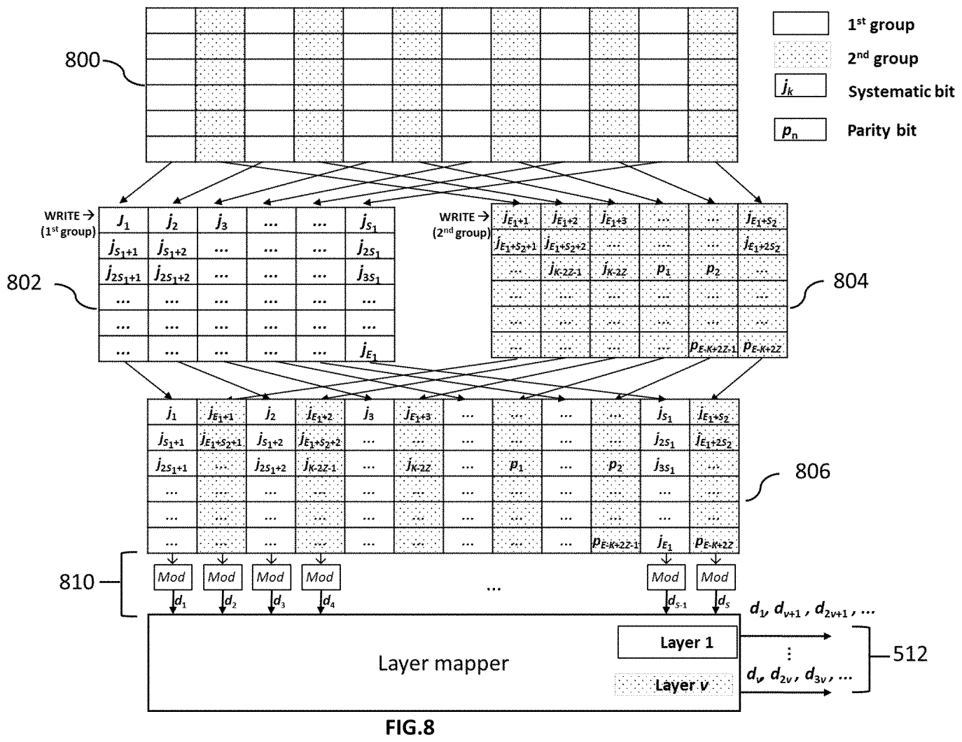

FIG. 8 explains the interleaving step S704, the modulation step S706 and the mapping step S708 of the method 700 in case of using two column groups. In the example shown in FIG. 8, a matrix 800 is created in the same manner as the matrix 300, i.e., it includes Qₘ rows and S=E/Qₘ columns Unlike the interleaver 106 (hereinafter referred to as the conventional interleaver 106 to highlight its relation to the prior art), the interleaver 604 divides the matrix 800 into a number G=2 of disjoint column groups 802 and 804 in the step S704. It should be again noted that two columns are in the same column group if they correspond to the same layer or different layers with similar transmission qualities (e.g., SNRs). Similar to FIG. 3, the columns of the matrix 800 which are related to the corresponding layer are shown in FIG. 8 by using different dotted-pattern fills (e.g., the columns provided with the densest dotted-pattern fill correspond to layer 1). The column groups 802 and 804 may be arranged in the decreasing order of the transmission qualities of the corresponding layers. In FIG. 8, it is assumed that the first column group 802 is constituted by the columns of the matrix 800 which correspond the layers with higher transmission qualities (e.g., which are above a certain threshold in decibels (dB) in case if the transmission qualities are represented by SNRs).

Referring to FIG. 8, the codeword 510 is written into the matrix 800 in G=2 steps. In the first step, the codeword bits (c₁, c₂, . . . c_{E}_{₁}) are written into the first column group 802, starting with writing the information bits; here, E₁ is the total number of bits in the first column group 802. In the second step, the subsequent codeword bits (c_{E}_{₁}₊₁, c_{E}_{₁}₊₂, . . . , c_{E}_{₁}_{+E}_{₂}) are written into the second column group 804, where E₂ is the total number of bits in the 2nd column group. If more than two column groups are used, this procedure will continue until, in the last step, the remaining codeword bits are written into the G -th column group. In all steps, the codeword bits are written row-wise, left to right, into the matrix 800, starting from the top row.

Once the codeword bits of the codeword 510 are all written into the column groups 802 and 804, the interleaver 604 proceeds to merge the column groups 802 and 804 to restore the matrix 800, i.e., its initial column arrangement, which is denoted by 806 in FIG. 8. Reading the codeword bits from the restored matrix 806 is accomplished by the interleaver 604 in the same way as it is done by the conventional interleaver 106, i.e., the output b=(b₁, . . . b_{E}) of the interleaver 604 is obtained by reading the restored matrix 806 column-wise, top to bottom, starting from the left-most column. The s-th column (s=1, . . . , S) of the restored matrix 806 produces a Qₘ-tuple of bits (b_{Q}_{ₘ}₍ₛ₋₁₎₊₁, b_{Q}_{ₘ}₍ₛ₋₁₎₊₂, . . . , b_{Q}_{ₘ}ₛ), which will be then mapped by the modulator 606 in the step 5706 to a complex modulation symbol dsₛ. It therefore turns out that the initial bits of any Qₘ-tuple represent the information bits. The modulator 606 produces a modulation symbol vector 810, i.e., d=(d₁, . . . , d_{S}), which is next mapped by the layer mapper 608 in the step S708 to the data transmission layers, thereby obtaining the layer-mapped modulation symbols 512.

If more than two column groups are formed in the interleaving step S704, and V_{g} is used as a number of data transmission layers in the g-th column group (g=1, . . . , G), then S_{g}=Sv_{g}/v is the number of the columns of the matrix 800 in the g-th column group, and E_{g}=S_{g}Qₘ is the total number of bits in the g-th column group.

It should be noted that, if a single column group (i.e., G=1) is used, the interleaver 604 writes the codeword bits into the matrix 800 in the same way as the conventional interleaver 106. In this case, reading the codeword bits from the matrix 800 is also done in the same way. Therefore, the interleaver 604 configured with one column group and the conventional interleaver 106 are exactly the same.

Whether, for the transmission of the codeword 510, it is convenient to use the conventional interleaver 106 or the interleaver 604 is determined based on a metric Δ_{CC}(ρ, g) which measures the total bit capacity increase in the codeword 510 (normalized by the codeword length E) that the interleaver 604 provides over the conventional interleaver 106. Here, ρ=(SNR₁, . . . , SNRᵥ) contains the layer SNRs (which are one example of the transmission qualities) and g=(γ₁, . . . , γᵥ) indicates the column groups, as noted above. The definition of Δ_{CC} is given by

$${Δ}_{CC} ( ρ , g ) = \frac{1}{E} {\sum }_{e = 1}^{K} [ {β}_{{l}_{604} ( e )}^{( {Q}_{m} )} ( {SNR}_{604} ( e ) ) - {β}_{{l}_{106} ( e )}^{( {Q}_{m} )} ( {SNR}_{106} ( e ) ) ] ,$$

where the summation is computed over the information bit indices e=1, . . . , K in the codeword 510, β is the bit capacity that is defined as shown above when discussing FIG. 3; l₆₀₄(e) gives the position of the e-th information bit in the Qₘ-tuple when using the interleaver 604, l₁₀₆(e) gives the position of the e-th information bit in the Qₘ-tuple when using the conventional interleaver 106; SNR₆₀₄(e) and SNR₁₀₆(e) are the SNRs of the e-th information bit when using the interleaver 604 and the conventional interleaver 106, respectively. In the above equation, β is independent of the interleaver used, whereas the interleavers' different mappings are captured by l₆₀₄(e), SNR₆₀₄(e) for the interleaver 604 and by l₁₀₆(e), SNR₁₀₆(e) for the conventional interleaver 106. l₁₀₆(e) and SNR₁₀₆(e) are obtained by applying the conventional interleaver mapping illustrated in FIG. 3. l₆₀₄(e) and SNR₆₀4(e) are obtained by applying the interleaver mapping illustrated in FIG. 8.

Numerical evaluations have shown that Δ_{CC} provides a good indication of the gain obtained by the interleaver 604—when Δ_{CC} is positive, the interleaver 604 has better performance than the conventional interleaver 106, whereas the negative Δ_{CC} indicates that the conventional interleaver 106 has better performance Therefore, the interleaver selection may be made based on the sign of Δ_{CC}.

Let us now consider one numerical example that explains how to use Δ_{CC}.

Assume that the codeword 510 is obtained by using an LDPC code, and it is required to perform the segmental transmission of the codeword 510 with a code rate R_{C}=½ by using the 16QAM (Qₘ=4) on two data transmission layers (v=2) (e.g., MIMO layers). The average SNR is assumed to be 7 dB. Further assume that, in the first transmission of one codeword segment of the codeword 510, there is a small SNR difference of Δ_{SNR}=2 dB between the two layers—SNR₁=8 dB and SNR₂=6 dB, whereas, in the second transmission of another codeword segment of the codeword 510, the SNR difference between the two layers is Δ_{SNR}=10 dB−SNR₁=12 dB, SNR₂=2 dB. The interleaver 604 produces two column groups, each containing one column (i.e., g=(1,2)). Table 2 given below summarizes the above evaluation assumptions.

TABLE 2
Evaluations in the above numerical example.

| | Code | Modulation | | Layer 1 | Layer 2 | |
|---|---|---|---|---|---|---|
| Transmission | rate | order | Avg. | SNR | SNR | |
| # | (R_{C}) | (Qₘ) | SNR | (SNR₁) | (SNR₂) | Δ_{SNR} |
| 1 | ½ | 4 | 7 dB | 8 dB | 6 dB | 2 dB |
| 2 | ½ | 4 | 7 dB | 12 dB | 2 dB | 10 dB |

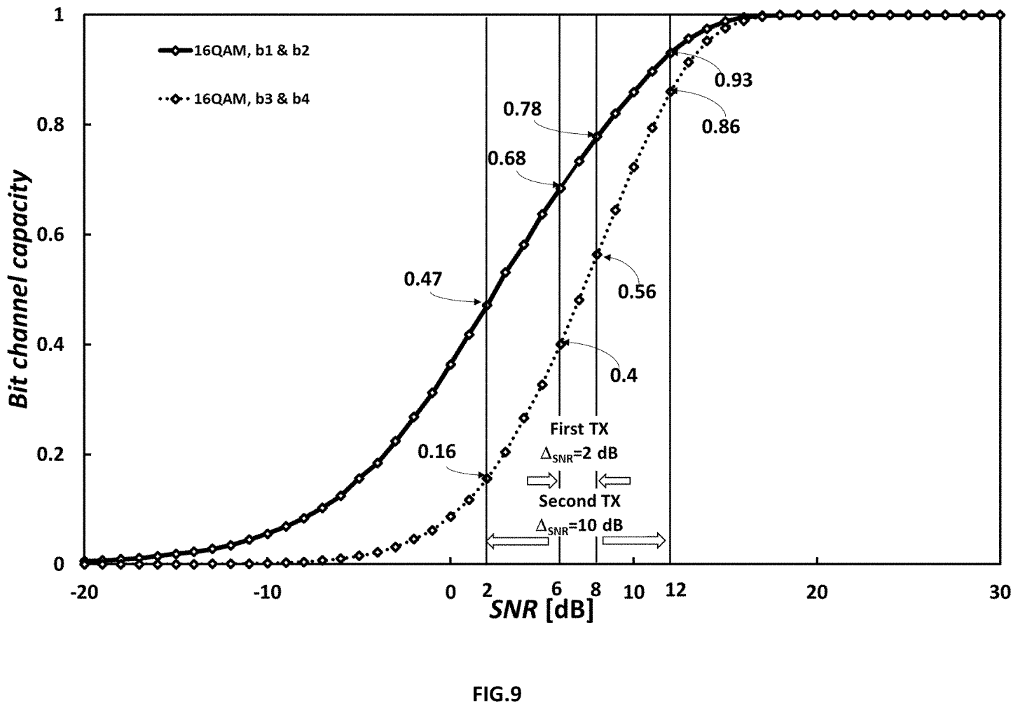

FIG. 9 shows dependencies βₗ⁽⁴⁾(SNR), l=1, . . . , 4, for the above numerical example with the 16QAM (Qₘ=4). In FIG. 9, pairs of vertical lines corresponding to the SNR differences between the two layers in case of the first and second transmissions intersect the dependences βₗ⁽⁴⁾(SNR), thereby yielding the bit capacity of each codeword bit in each tuple of codeword bits. In this case, each 4-tuple of codeword bits is represented by four codeword bits b1, b2, b3, b4, where b1 is the first bit in the 4-tuple, b2 is the 2^{nd} bit, and so on. In the first transmission, the bit capacity of the codeword bits b1 and b2 is 0.78 and the bit capacity of the codeword bits b3 and b4 is 0.56 in case of using the first data transmission layer, while the bit capacity of the code the bit capacity of the codeword bits b1 and b2 is 0.68 and the bit capacity of the codeword bits b3 and b4 is 0.4 in case of using the second data transmission layer. In the second transmission, the bit capacity of the codeword bits b1 and b2 is 0.93 and the bit capacity of the codeword bits b3 and b4 is 0.86 in case of using the first data transmission layer, while the bit capacity of the code the bit capacity of the codeword bits b1 and b2 is 0.47 and the bit capacity of the codeword bits b3 and b4 is 0.16 in case of using the second data transmission layer.

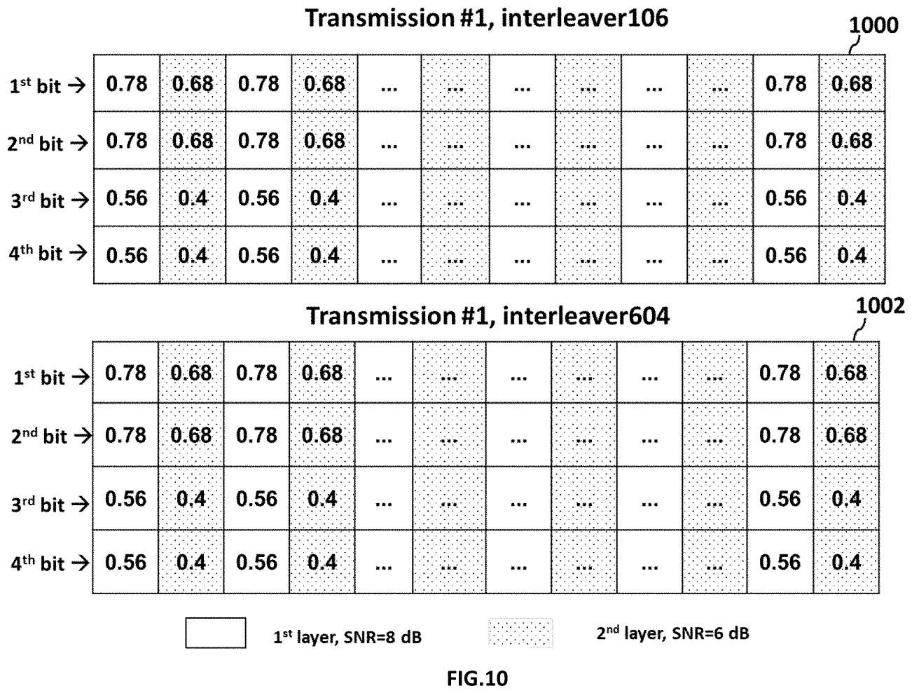

FIG. 10 shows matrices 1000 and 1002 used by the conventional interleaver 106 and the interleaving 604, respectively, and the corresponding bit capacities for the first transmission in the above numerical example. In FIG. 10, different dotted-pattern fills are again used to show the correspondence of the columns of the matrices 1000, 1002 to the two data transmission layers (e.g., the columns provided with the densest dotted-pattern correspond to the first data transmission layer). Moreover, boldface numbers indicate positions of information bits. As the code rate is ½, the information bits occupy half of each matrix regardless of the interleaver used. The conventional interleaver 106 writes the information bits row-wise into all columns (i.e., in other words, on the two data transmission layers), for which reason it fills the two higher rows with the information bits (see the upper part of FIG. 10). Therefore, one half of the information bits enjoy the bit capacity of 0.78 and another half enjoy the bit capacity of 0.68. Unlike the conventional interleaver 106, the interleaver 604 writes the information bits into the columns corresponding to the first data transmission layer only (see the lower part of FIG. 10). It means that one half of the information bits enjoy the bit capacity of 0.78 and another half enjoy the bit capacity of 0.56.

Let us now compute Am by applying the above equation. To do this, it is required to determine the positions l₆₀₄(e) and l₁₀₆(e) in the in Qₘ-tuple and the values SNR₆₀₄(e) and SNR₁₀₆(e) of the data transmission layers on which the e -th bit is transmitted for each information bit (e=1, . . . , K). The values l₁₀₆(e) and SNR₁₀₆(e) are obtained by the interleaver mapping illustrated in FIG. 3; the corresponding bit capacities are determined from the upper part of FIG. 10. The values l₆₀₄(e) and SNR₆₀₄(e) are obtained by the interleaver mapping illustrated in FIG. 8; the corresponding bit capacities are determined from the lower part of FIG. 10. These values are shown in Table 3 below.

TABLE 3
Bit positions, SNRs and corresponding bit capacities for the first transmission.

| | Interleaver 106 | | | Interleaver 604 | | | |
|---|---|---|---|---|---|---|---|
| | | | βₗ_{₁₀₆}⁽⁴⁾ | | | βₗ_{₆₀₄}⁽⁴⁾ | βₗ_{₆₀₄}⁽⁴⁾ (SNR₆₀₄) − |
| e | l₁₀₆ | SNR₁₀₆ | (SNR₁₀₆) | l₆₀₄ | SNR₆₀₄ | (SNR₆₀₄) | βₗ_{₁₀₆}⁽⁴⁾ (SNR₁₀₆) |
| 1 | 1 | 8 | 0.78 | 1 | 8 | 0.78 | 0 |
| 2 | 1 | 6 | 0.68 | 1 | 8 | 0.78 | 0.1 |
| . . . | . . . | . . . | . . . | . . . | . . . | . . . | . . . |
| K/4 − 1 | 1 | 8 | 0.78 | 1 | 8 | 0.78 | 0 |
| K/4 | 1 | 6 | 0.68 | 1 | 8 | 0.78 | 0.1 |
| K/4 + 1 | 1 | 8 | 0.78 | 2 | 8 | 0.78 | 0 |
| K/4 + 2 | 1 | 6 | 0.68 | 2 | 8 | 0.78 | 0.1 |
| . . . | . . . | . . . | . . . | . . . | . . . | . . . | . . . |
| K/2 − 1 | 1 | 8 | 0.78 | 2 | 8 | 0.78 | 0 |
| K/2 | 1 | 6 | 0.68 | 2 | 8 | 0.78 | 0.1 |
| K/2 + 1 | 2 | 8 | 0.78 | 3 | 8 | 0.56 | −0.22 |
| K/2 + 2 | 2 | 6 | 0.68 | 3 | 8 | 0.56 | −0.12 |
| . . . | . . . | . . . | . . . | . . . | . . . | . . . | . . . |
| 3K/4 − 1 | 2 | 8 | 0.78 | 3 | 8 | 0.56 | −0.22 |
| 3K/4 | 2 | 6 | 0.68 | 3 | 8 | 0.56 | −0.12 |
| 3K/4 + 1 | 2 | 8 | 0.78 | 4 | 8 | 0.56 | −0.22 |
| 3K/4 + 2 | 2 | 6 | 0.68 | 4 | 8 | 0.56 | −0.12 |
| . . . | . . . | . . . | . . . | . . . | . . . | . . . | . . . |
| K − 1 | 2 | 8 | 0.78 | 4 | 8 | 0.56 | −0.22 |
| K | 2 | 6 | 0.68 | 4 | 8 | 0.56 | −0.12 |

Δ_{CC} is obtained by summing the numbers in the rightmost column of Table 3 and dividing the results by E. In the rightmost column of Table 3, there are K/4 values=0, K/4 values=0.1, K/4 values=−0.12 and K/4 values=−0.22. Therefore, Δ_{CC} for the first transmission is obtained as follows:

$${Δ}_{CC} = \frac{1}{E} [ 0 \times \frac{K}{4} + 0.1 \times \frac{K}{4} - 0.12 \times \frac{K}{4} - 0.22 \times \frac{K}{4} ] = - 0.03 ,$$

where K/E=R_{C}=½ has been used. The negative Δ_{CC} indicates that the conventional interleaver 106 provides better performance compared to the interleaver 604.

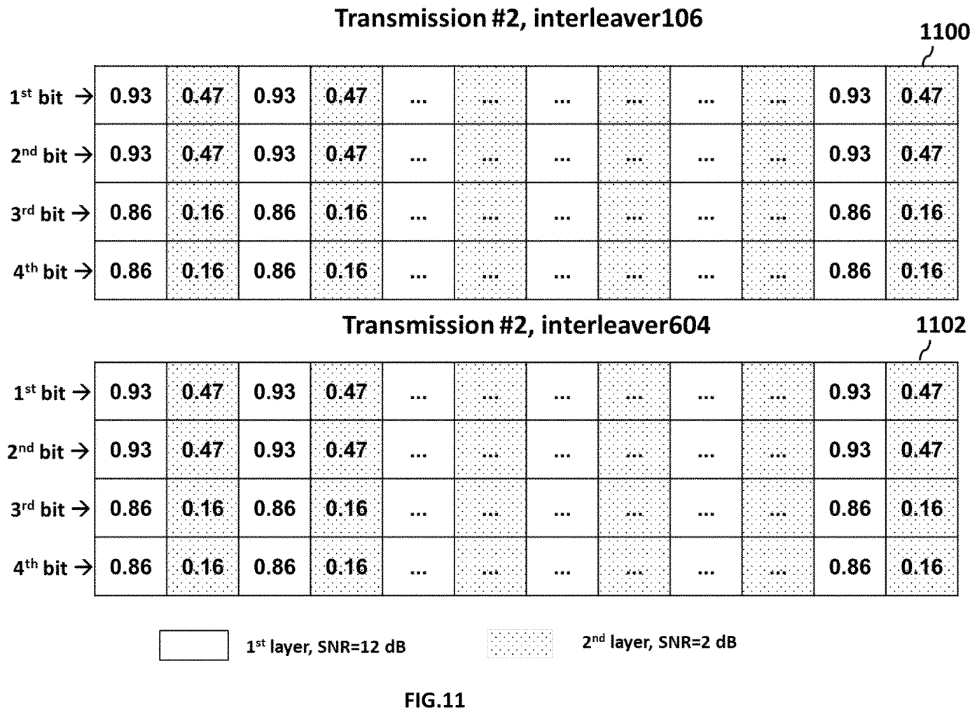

FIG. 11 shows matrices 1100 and 1102 used by the conventional interleaver 106 and the interleaving 604, respectively, and the corresponding bit capacities for the second transmission in the above numerical example. In FIG. 11, different dotted-pattern fills are again used to show the correspondence of the columns of the matrices 1100, 1102 to the two data transmission layers (e.g., the columns provided with the densest dotted-pattern correspond to the first data transmission layer). Moreover, boldface numbers again indicate the positions of the information bits. As follows from FIG. 11, in case of using the conventional interleaver 106, one half of the information bits enjoy the bit capacity of 0.93 and another half enjoy the bit capacity of 0.47. In case of using the interleaver 604, one half of the information bits enjoy the bit capacity of 0.93 and another half enjoy the bit capacity of 0.86. Similar to Table 3, Table 4 given below list the positions l₆₀₄(e) and l₁₀₆(e) in the Qₘ-tuple, the values SNR₆₀₄(e) and SNR₁₀₆(e) of the two data transmission layers on which the e-th bit is transmitted (e=1, . . . , K), as well as the bit capacities for the second transmission.

Table 4. Bit positions, SNRs and corresponding bit capacities for the second transmission.

TABLE 4
Bit positions, SNRs and corresponding bit capacities for the second transmission.

| | Interleaver 106 | | | Interleaver 604 | | | |
|---|---|---|---|---|---|---|---|
| | | | βₗ_{₁₀₆}⁽⁴⁾ | | | βₗ_{₆₀₄}⁽⁴⁾ | βₗ_{₆₀₄}⁽⁴⁾ (SNR₆₀₄) − |
| e | l₁₀₆ | SNR₁₀₆ | (SNR₁₀₆) | l₆₀₄ | SNR₆₀₄ | (SNR₆₀₄) | βₗ_{₁₀₆}⁽⁴⁾ (SNR₁₀₆) |
| 1 | 1 | 12 | 0.93 | 1 | 12 | 0.93 | 0 |
| 2 | 1 | 2 | 0.47 | 1 | 12 | 0.93 | 0.46 |
| . . . | . . . | . . . | . . . | . . . | . . . | . . . | . . . |
| K/4 − 1 | 1 | 12 | 0.93 | 1 | 12 | 0.93 | 0 |
| K/4 | 1 | 2 | 0.47 | 1 | 12 | 0.93 | 0.46 |
| K/4 + 1 | 1 | 12 | 0.93 | 2 | 12 | 0.93 | 0 |
| K/4 + 2 | 1 | 2 | 0.47 | 2 | 12 | 0.93 | 0.46 |
| . . . | . . . | . . . | . . . | . . . | . . . | . . . | . . . |
| K/2 − 1 | 1 | 12 | 0.93 | 2 | 12 | 0.93 | 0 |
| K/2 | 1 | 2 | 0.47 | 2 | 12 | 0.93 | 0.46 |
| K/2 + 1 | 2 | 12 | 0.93 | 3 | 12 | 0.86 | −0.07 |
| K/2 + 2 | 2 | 2 | 0.47 | 3 | 12 | 0.86 | 0.39 |
| . . . | . . . | . . . | . . . | . . . | . . . | . . . | . . . |
| 3K/4 − 1 | 2 | 12 | 0.93 | 3 | 12 | 0.86 | −0.07 |
| 3K/4 | 2 | 2 | 0.47 | 3 | 12 | 0.86 | 0.39 |
| 3K/4 + 1 | 2 | 12 | 0.93 | 4 | 12 | 0.86 | −0.07 |
| 3K/4 + 2 | 2 | 2 | 0.47 | 4 | 12 | 0.86 | 0.39 |
| . . . | . . . | . . . | . . . | . . . | . . . | . . . | . . . |
| K − 1 | 2 | 12 | 0.93 | 4 | 12 | 0.86 | −0.07 |
| K | 2 | 2 | 0.47 | 4 | 12 | 0.86 | 0.39 |

Δ_{CC} is obtained by summing the numbers in the rightmost column of Table 4 and dividing the results by E. In the rightmost column of Table 4, there are K/4 values=0, K/4 values=0.46, K/4 values=−0.07 and K/4 values=0.39. Therefore, Δ_{CC} or the second transmission is obtained as follows:

$${Δ}_{CC} = \frac{1}{E} [ 0 \times \frac{K}{4} + 0.46 \times \frac{K}{4} - 0.07 \times \frac{K}{4} + 0.39 \times \frac{K}{4} ] = 0.098 .$$

The positive Δ_{CC} above indicates that the interleaver 604 provides better performance compared to the conventional interleaver 106.

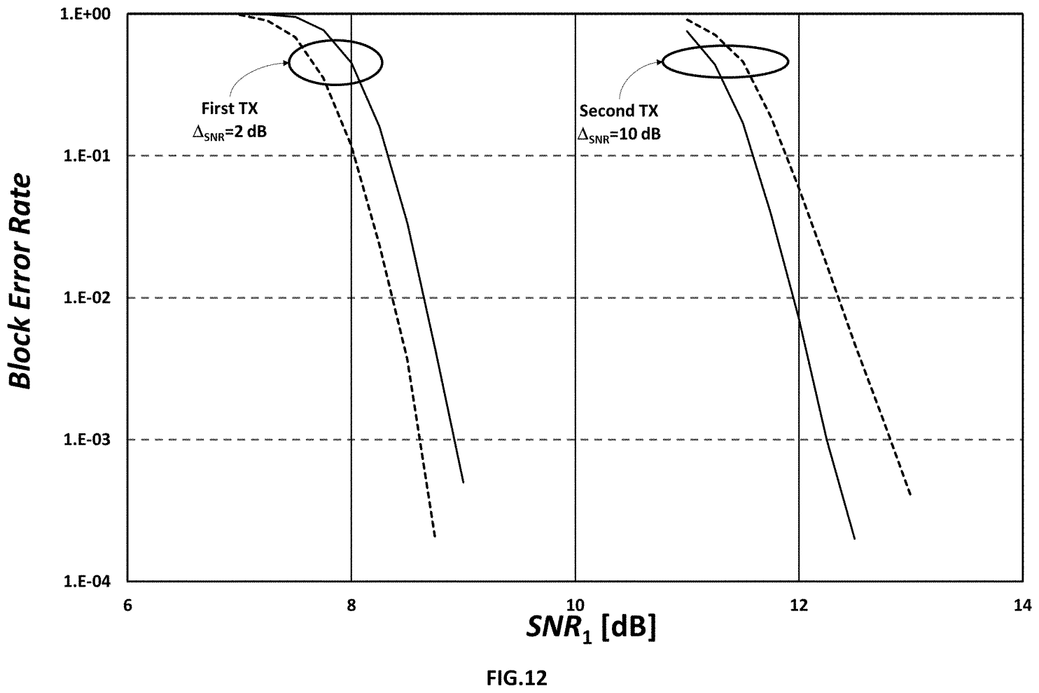

FIG. 12 shows dependencies of a Block Error Rate (BLER) on SNR for the two transmissions in the above numerical example. In FIG. 12, the dashed lines correspond to the conventional interleaver 106, while the solid lines correspond to the interleaver 604. The dependences BLER(SNR) confirm the above conclusions. For the first transmission (SNR=8 dB), the conventional interleaver 106 has a smaller BLER than the interleaver 604. For the second transmission (SNR=12 dB), the interleaver 604 provides a smaller BLER. It can be further concluded that data transmission layers with similar SNRs should be in the same column group, while data transmission layers with significantly different SNRs should be in separate column groups.

Thus, the above numerical example clearly shows how to decide on the conventional 106 and the interleaver 604 based on the sign of Δ_{CC}(ρ, g). At the same time, Δ_{CC}(ρ, g) allows one to find the best column grouping configuration g*. It can be done as follows:

$${g}^{*} ( ρ ) = arg {max}_{g} {Δ}_{CC} ( ρ , g ) .$$

If the best column grouping obtained from the above equation turns out to be g*=(1, . . . ,1), all the columns are in the same column group, which means that the conventional interleaver 106 is the best choice, i.e., it provides the best performance. When g*≠(1, . . . ,1), the best performance is obtained by the interleaver 604 configured with the best column grouping g*.

Searching for the best column grouping configuration g* may be done numerically by computing Δ_{CC}(ρ, g) for all admitted column grouping configurations g. In general, as there are up to v column groups, each of the v elements of g can take a value between 1 and v. For a given column grouping configuration, this leads to a number of admitted values of the order of v^{v}—a rather large number, even for small v. The searching complexity may be greatly reduced by recalling that only data transmission layers with similar SNRs may be in the same column group, as concluded above. Thus, the following searching strategy may be applied:
1. sorting the data transmission layers according to their SNRs;
2. for each pair of adjacent data transmission layers, evaluating whether they should be in the same column group or not.

As there are v−1 pairs of adjacent data transmission layers, the number of admitted column grouping configurations drops from v^{v} to 2^{v-1}. Therefore, it is required to evaluate Δ_{CC}(ρ, g) only for 2^{v-1} times. In the NR, the maximum number of MIMO layers (which are one example of the data transmission layers) for one codeword is v=4. Therefore, the number of admitted column grouping configurations would be of the order of v^{v}=256. With the above searching strategy, the number of admitted column grouping configurations is reduced to 2^{v-1}=8.

The performance of the LDPC-coded transmission in the above numerical example is evaluated on the MIMO channel with v layers and with G column groups where the MIMO layers have the same SNR within each column group. Without loss of generality, one may assume that the first column group has higher SNR than other column groups, and the g-th column group SNR is □_{SNR,g} [dB] smaller than the SNR of the first column group. The channel model is represented by the additive white Gaussian noise (AWGN). The performance evaluation assumptions are summarized in Table 5 given below. The performance gain is evaluated based on the SNR needed to achieve the BLER≤10⁻².

TABLE 5
Summary of simulation parameters (a
subset of combinations is evaluated).

| Parameter | Value |
|---|---|
| LDPC code rate (R_{C} = K/E) | ¼, ½, ⅔ |
| Modulations | QPSK, 16QAM, 64QAM |
| Number of layers (ν) | 2, 4 |
| Number or time-frequency REs | 80, 1024 |
| Channel model | AWGN |
| SNR difference between layers □_{SNR, g} [dB] | 3, 6, 10, 12, 15, 18, 24 |
| LDPC decoder | Belief-propagation, |
| | 50 iterations |

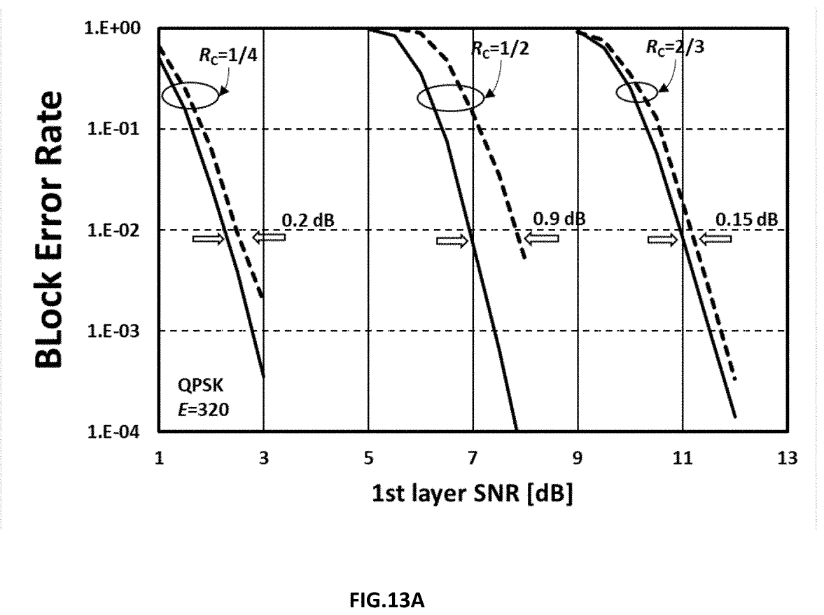

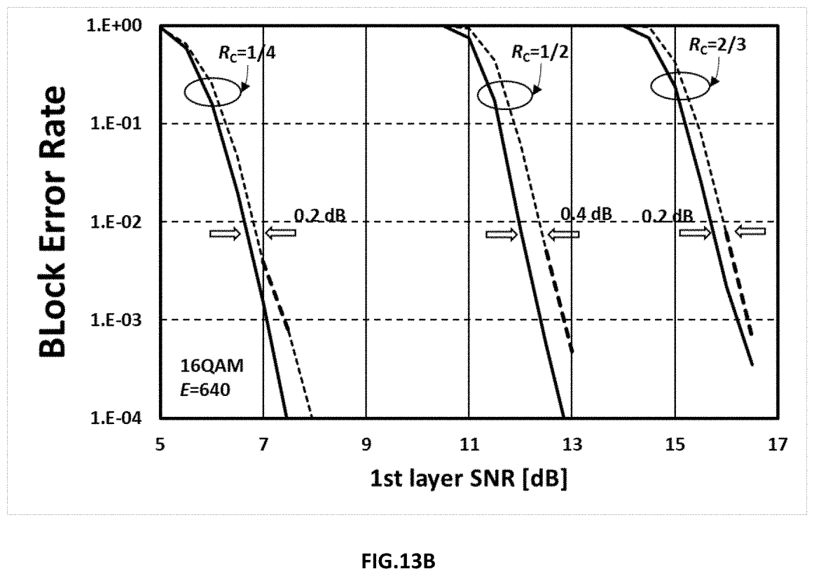

FIGS. 13A and 13B show the BLER performance of QPSK-modulated and 16QAM-modulated LDPC-coded transmission on v=2 MIMO layers and G=2 column groups. In FIGS. 13A and 13B, the solid curves show the performance obtained with the interleaver 604, while the dashed curves show the performance obtained with the conventional interleaver 106. The SNR difference between the MIMO layers is □_{SNR}=10 dB. It can be observed that the interleaver 604 performs uniformly better than the conventional interleaver 106. SNR gains up to 0.9 dB are observed with the QPSK modulation and the LDPC code rate ½ (see FIG. 13A). SNR gains are slightly smaller but still significant with the 16QAM (see FIG. 13B).

It is observed in FIGS. 13A and 13B that higher order modulations provide lower gains. When the layer SNR difference is small, the conventional interleaver 106 already maps the information bits to the bit channels with the highest bit capacity. Thus, there is no gain. In order to have gains with a high-order modulation, the layer SNR difference must be large enough so that the smallest bit capacity on the high-SNR layer(s) is larger than the largest bit capacity on the low-SNR layer(s). Thus, for each modulation order, there is a minimum SNR difference below which the interleaver 604 provides no gain or even loss. That minimum SNR difference is 0 dB for the QPSK, roughly 6 dB for the 16QAM, and roughly 10 dB for the 64QAM. Therefore, for a given and fixed SNR difference, the higher the modulation order is, the smaller the gain is.

It is also observed in FIGS. 13A and 13B that, for any given modulation and given SNR, the largest gain is achieved with the code rate

$${R}_{C} = \frac{K}{E} = \frac{1}{2} ,$$

whereas the gain is smaller for code rates ¼ and ⅔. Such behaviour is connected to the fundamental observation that the best belief-propagation decoding performance is obtained when the information bits are mapped to the bit channels with the highest bit capacity.

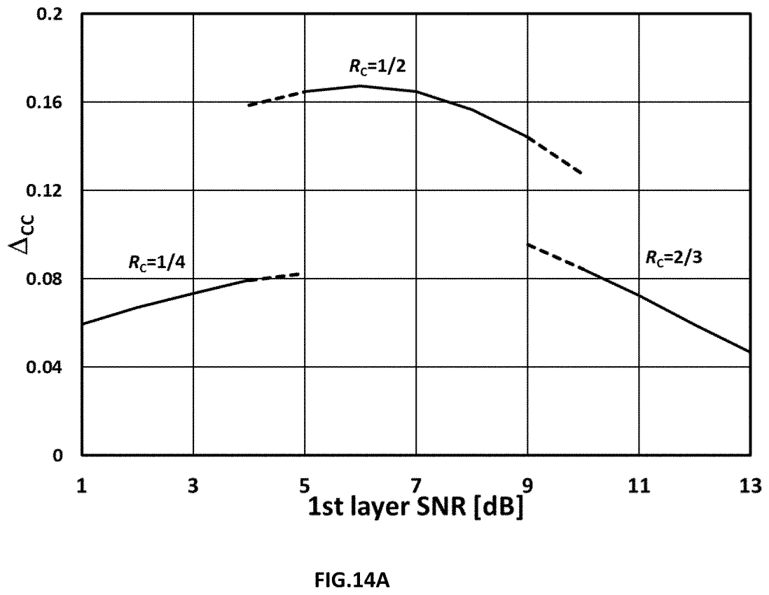

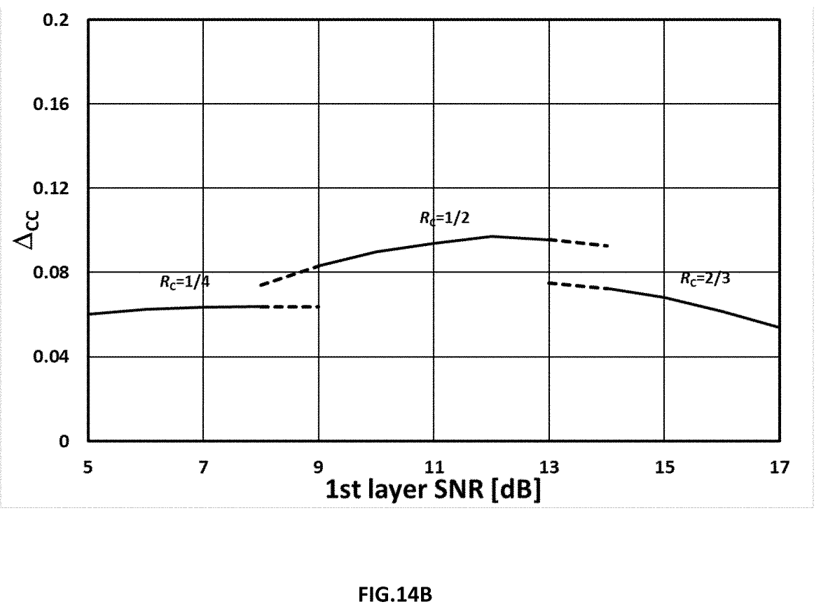

FIGS. 14A and 14B show Δ_{CC}(SNR) for the same code rates and modulations as used for FIGS. 13A and 13B. The curve Δ_{CC}(SNR) has multiple branches—one branch for each code rate. In FIGS. 14A and 14B, each branch is shown in the range of SNRs surrounding the SNR point at which the BLER=10⁻². It can be seen that Δ_{CC} for the branch corresponding to code rate ½ is higher than for the other branches. The comparison of FIGS. 13A, 13B and FIGS. 14A, 14B reveals a clear correlation between Δ_{CC} and the gain of the interleaver 604. For code rate ½, the gain and Δ_{CC} is larger than for other code rates. For higher-order modulations, ACC depends on the code rate and the SNRs of all MIMO layers. This makes the derivation of the best code rate more difficult.

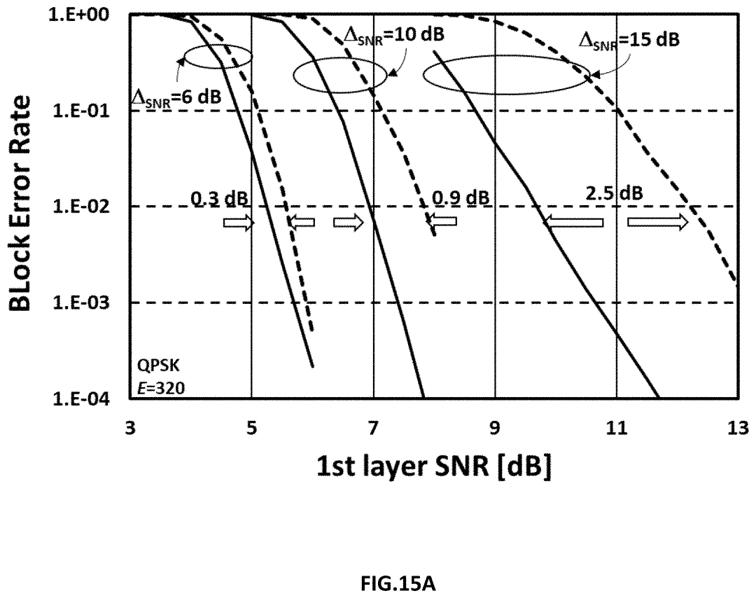

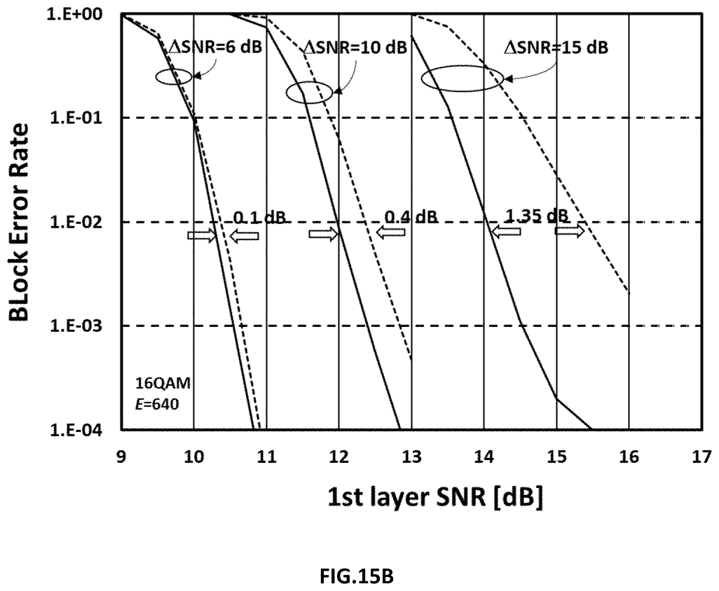

FIGS. 15A and 15B show the BLER performance of the QPSK-modulated and 16QAM-modulated LDPC-coded transmission for various layer SNR differences. In FIGS. 15A and 15B, the solid curves show the BLER performance obtained with the interleaver 604, while the dashed curves show the BLER performance obtained with the conventional interleaver 106. In this case, the code rate is R_{C}=½. The interleaver 604 performs uniformly better than the convention interleaver 106. SNR gains up to 2.7 dB are observed with the QPSK and □_{SNR}=15 dB (see FIG. 15A). With the 16QAM, SNR gains up to 1.7 dB are observed when □_{SNR}=15 dB (see FIG. 15B).

It should be noted that each step or operation of the method 700, or any combinations of the steps or operations, can be implemented in various manners, such as hardware, firmware, and/or software. As an example, one or more of the steps or operations described above can be embodied by processor executable instructions, data structures, program modules, and other suitable data representations. Furthermore, the executable instructions which embody the steps or operations described above can be stored on a corresponding data carrier and executed by the processor 502. This data carrier can be implemented as any non-transitory computer-readable storage medium configured to be readable by said at least one processor to execute the processor executable instructions. Such non-transitory computer-readable storage media can include both volatile and nonvolatile media, removable and non-removable media. By way of example, and not limitation, the non-transitory computer-readable media include media implemented in any method or technology suitable for storing information. In more detail, the practical examples of the computer-readable media include, but are not limited to information-delivery media, RAM, ROM, EEPROM, flash memory or other memory technology, CD-ROM, digital versatile discs (DVD), holographic media or other optical disc storage, magnetic tape, magnetic cassettes, magnetic disk storage, and other magnetic storage devices.

Although the exemplary embodiments are described herein, it should be noted that any various changes and modifications could be made in the embodiments without departing from the scope of the embodiments.

1. An apparatus for a wireless communication system, comprising:
a processor;
a memory coupled to the processor and configured to store processor-executable instructions, wherein the processor is configured, when executing the processor-executable instructions, to:
receive a codeword to be sent over data transmission layers, —wherein each of the data transmission layers has a transmission quality, the codeword obtained using a linear code, the codeword having a codeword length E and comprising codeword bits, the codeword bits comprising at least one information bit and at least one parity bit;
interleave the codeword bits by using a matrix with n rows and k columns, where n and k are selected based on a predefined modulation scheme and the codeword length E, each of the columns corresponding to one of the data transmission layers, and said interleaving comprising:
arranging, into at least one first column group, the columns corresponding to the data transmission layers whose transmission qualities are equal to or above a threshold;
arranging, into at least one second column group, the columns corresponding to the data transmission layers whose transmission qualities are below the threshold;
writing the codeword bits row-wise into the at least one first column group and the at least one second column group, starting with writing the at least one information bit row-wise into the at least one first column group;
merging the at least one first column group and the at least one second column group to restore the matrix; and
reading the codeword bits column-wise from the matrix;
obtain, by using the predefined modulation scheme, a modulation symbol for the codeword bits read from each column of the matrix; and
map the modulation symbol to the data transmission layers; and
a transceiver configured to send the mapped modulation symbols to a target wireless communication apparatus.

2. The apparatus of claim 1, wherein the predefined modulation scheme has a modulation order Qₘ, and wherein n is equal to the modulation order Qₘ, while k is obtained by applying a floor or ceiling function to a ratio of the codeword length E to the modulation order Qₘ.

3. The apparatus of claim 2, wherein the processor is further configured, before said interleaving, to determine the modulation order Qₘ of the predefined modulation scheme based on the transmission qualities of the data transmission layers.

4. The apparatus of claim 2, wherein the predefined modulation scheme defines a mapping of a Qₘ-tuple of the codeword bits for each column of the matrix to the modulation symbol, and wherein the processor is further configured to:
determine bit capacities of the codeword bits in each Qₘ-tuple based on the transmission qualities of the data transmission layers; and
based on the determined bit capacities, determine: (i) a number G of the at least one first column group and the at least one second column group into which the columns of the matrix are to be arranged, and (ii) a correspondence of each of the data transmission layers to the at least one first column group or the at least one second column group.

5. The apparatus of claim 4, wherein the processor is further configured, before causing the transceiver to send the mapped modulation symbols, to:
generate a control message comprising at least one of:
the modulation order Qₘ;
the codeword length E;
the number G of the at least one first column group and the at least one second column group used when interleaving the codeword bits; and
the correspondence of each of the data transmission layers to the at least one first column group or the at least one second column group; and
cause the transceiver to send the control message to the target wireless communication apparatus.

6. The apparatus of claim 1, wherein the codeword is obtained using the linear code selected from one of a turbo code, a systematic code, a systematic polar code, and a Low-Density Parity-Check (LDPC) code.

7. The apparatus of claim 1, wherein the predefined modulation scheme comprises one of a quadrature amplitude modulation (QAM) scheme, a Phase Shift Keying (PSK) modulation scheme, and a Quadrature PSK (QPSK) modulation scheme.

8. A method for wireless communications, comprising:
receiving a codeword to be sent over data transmission layers, each of the data transmission layers having a transmission quality, the codeword obtained using a linear code, the codeword having a codeword length E and comprising codeword bits, the codeword bits comprising at least one information bit and at least one parity bit;
interleaving the codeword bits by using a matrix with n rows and k columns, where n and k are selected based on a predefined modulation scheme and the codeword length E, each of the columns corresponding to one of the data transmission layers, and said interleaving comprising:
arranging, into at least one first column group, the columns corresponding to the data transmission layers whose transmission qualities are equal to or above a threshold;
arranging, into at least one second column group, the columns corresponding to the data transmission layers whose transmission qualities are below the threshold;
writing the codeword bits row-wise into the at least one first column group and the at least one second column group, starting with writing the at least one information bit row-wise into the at least one first column group;
merging the at least one first column group and the at least one second column group to restore the matrix; and
reading the codeword bits column-wise from the matrix;
obtaining, by using the predefined modulation scheme, a modulation symbol for the codeword bits read from each column of the matrix;
mapping the modulation symbols to the data transmission layers; and
sending the mapped modulation symbols to a target wireless communication apparatus.

9. The method of claim 8, wherein the predefined modulation scheme has a modulation order Qₘ and n is equal to the modulation order (Qₘ), while k is obtained by applying a floor or ceiling function to a ratio of the codeword length E to the modulation order Qₘ.

10. The method of claim 9, further comprising, before the interleaving:
determining the modulation order Qₘ of the predefined modulation scheme based on the transmission qualities of the data transmission layers.

11. The method of claim 9, wherein the predefined modulation scheme defines a mapping of a Qₘ-tuple of the codeword bits for each column of the matrix to the modulation symbol, and wherein the method further comprises:
determining bit capacities of the codeword bits in each Qₘ-tuple based on the transmission qualities of the data transmission layers; and
based on the determined bit capacities, determining: (i) a number G of the at least one first column group and the at least one second column group into which the columns of the matrix are to be arranged, and (ii) a correspondence of each of the data transmission layers to the at least one first column group or the at least one second column group.

12. The method of claim 11, further comprising, before sending the mapped modulation symbols:
generating a control message comprising at least one of:
the modulation order Qₘ;
the codeword length E;
the number G of the at least one first column group and the at least one second column group used when interleaving the codeword bits; and
the correspondence of each of the data transmission layers to the at least one first column group or the at least one second column group; and
sending the control message to the target wireless communication apparatus.

13. The method of claim 8, further comprising:
determining the transmission qualities of the data transmission layers in advance based on uplink reference signals in case of Time-Division Duplexing (TDD) communications or downlink reference signals in case of Frequency-Division Duplexing (FDD) communications.

14. The method of claim 8, wherein the data transmission layers comprise Multiple-Input Multiple-Output (MIMO) spatial layers.

15. A non-transitory computer readable medium storing instructions that are executable by a computer, the non-transitory computer readable medium is applied to a first communication apparatus, and the instructions comprise instructions for:
receiving a codeword to be sent over data transmission layers, each of the data transmission layers having a transmission quality, the codeword obtained using a linear code, the codeword having a codeword length E and comprising codeword bits, the codeword bits comprising at least one information bit and at least one parity bit;
interleaving the codeword bits by using a matrix with n rows and k columns, where n and k are selected based on a predefined modulation scheme and the codeword length E, each of the columns corresponding to one of the data transmission layers, and said interleaving comprising:
arranging, into at least one first column group, the columns corresponding to the data transmission layers whose transmission qualities are equal to or above a threshold;
arranging, into at least one second column group, the columns corresponding to the data transmission layers whose transmission qualities are below the threshold;
writing the codeword bits row-wise into the at least one first column group and the at least one second column group, starting with writing the at least one information bit row-wise into the at least one first column group;
merging the at least one first column group and the at least one second column group to restore the matrix; and
reading the codeword bits column-wise from the matrix;
obtaining, by using the predefined modulation scheme, a modulation symbol for the codeword bits read from each column of the matrix;
mapping the modulation symbols to the data transmission layers; and
sending the mapped modulation symbols to a target wireless communication apparatus.

16. The non-transitory computer readable medium according to claim 15, wherein the predefined modulation scheme has a modulation order (Qₘ and n is equal to the modulation order (Qₘ), while k is obtained by applying a floor or ceiling function to a ratio of the codeword length E to the modulation order Qₘ.

17. The non-transitory computer readable medium according to claim 16, wherein the instructions further comprise instructions for:
before the interleaving, determining the modulation order Qₘ of the predefined modulation scheme based on the transmission qualities of the data transmission layers.

18. The non-transitory computer readable medium according to claim 16, wherein the predefined modulation scheme defines a mapping of a Qₘ-tuple of the codeword bits for each column of the matrix to the modulation symbol, and wherein the instructions further comprise instructions for:
determining bit capacities of the codeword bits in each Qₘ-tuple based on the transmission qualities of the data transmission layers; and
based on the determined bit capacities,
determining:
(i) a number G of the at least one first column group and the at least one second column group into which the columns of the matrix are to be arranged, and
(ii) a correspondence of each of the data transmission layers to the at least one first column group or the at least one second column group.

19. The non-transitory computer readable medium according to claim 18, wherein the instructions further comprise instructions for:
before sending the mapped modulation symbols,
generating a control message comprising at least one of:
the modulation order Qₘ;
the codeword length E;
the number G of the at least one first column group and the at least one second column group used when interleaving the codeword bits; and
the correspondence of each of the data transmission layers to the at least one first column group or the at least one second column group; and
sending the control message to the target wireless communication apparatus.

20. The non-transitory computer readable medium according to claim 15, wherein the codeword is obtained using the linear code selected from one of a turbo code, a systematic code, a systematic polar code, and a Low-Density Parity-Check (LDPC) code.
